(19) United States
(12) Patent Application Publication
(10) Pub. No.: US 2025/0240880 A1
(43) Pub. Date: Jul. 24, 2025

(54) DISPLAY DEVICE

(71) Applicant: LG Display Co., Ltd., Seoul (KR)

(72) Inventor: Binn KIM, Seoul (KR)

(21) Appl. No.: 18/921,745

(22) Filed: Oct. 21, 2024

(30) Foreign Application Priority Data
Jan. 18, 2024 (KR) 10-2024-0007830

(51) Int. Cl. H05K 1/02

(52) U.S. Cl. CPC H05K 1/0283; H05K 2201/09263; H05K 2201/10128

(57) ABSTRACT

A display device includes a stretchable lower substrate, a plurality of plate patterns disposed on the lower substrate and spaced apart from each other, a plurality of connection lines disposed between the plurality of plate patterns, and a plurality of reinforcement members disposed between the plurality of connection lines and spaced apart from the plurality of connection lines. The plurality of reinforcement members are formed in the vicinity of the plurality of connection lines to be spaced apart from the plurality of connection lines so that when the display device is stretched, excessive contraction of some of the plurality of connection lines due to the Poisson's effect may be suppressed.

### CROSS-REFERENCE TO RELATED APPLICATIONS

This application claims the priority of Korean Patent Application No. 10-2024-0007830 filed on Jan. 18, 2024, in the Korean Intellectual Property Office, the entire disclosure of which is incorporated herein by reference.

### BACKGROUND

### Technical Field

The present disclosure relates to a display device, and more particularly, but not exclusively, to a stretchable display device which minimizes or reduces a damage of a stretchable connection line.

### Description of the Related Art

As display devices which are used for a monitor of a computer, a television, a cellular phone, or the like, there are an organic light emitting display (OLED) device which is a self-emitting device, a liquid crystal display (LCD) device which utilizes a separate light source, and the like.

An applicable range of the display device is diversified to personal digital assistants as well as monitors of computers and televisions, and a display device with a large display area and a reduced volume and weight is being studied.

Recently, a display device which is manufactured by forming a display unit, a wiring line, and the like on a flexible substrate such as plastic which is a flexible material so as to be stretchable in a specific direction and changed in various forms is getting attention as a next generation display device. However, stretchable display devices have a number of challenges. For example, the connection lines between pixels on the flexible substrate are prone to being damage by repeated stretching, bending, and the like, which can distort image quality or render the display inoperative. Thus, it would be advantageous to have a stretchable display device that overcomes these and other deficiencies with current stretchable displays.

### BRIEF SUMMARY

One or more embodiments of the present disclosure provide a display device which suppresses excessive contraction of a connection line.

One or more embodiments of the present disclosure provide a display device which reduces the damage of the connection line due to excessive contraction.

One or more embodiments of the present disclosure provide a display device in which a reinforcement member which supports a connection line is formed in an area which is contracted due to Poisson's effect when it is stretched.

One or more embodiments of the present disclosure provide a display device which designs a length of the reinforcement member to be differentiated according to a degree of contraction for every area.

One or more embodiments of the present disclosure provide a display device which applies more or longer reinforcement members in an area which is relatively more contracted.

According to one or more embodiments of the present disclosure, a display device includes a stretchable lower substrate; a plurality of plate patterns which is disposed on the lower substrate to be spaced apart from each other; a plurality of connection lines disposed between the plurality of plate patterns; and a plurality of reinforcement members disposed between the plurality of connection lines, and the plurality of reinforcement members is disposed to be spaced apart from the plurality of connection lines. Accordingly, the plurality of reinforcement members is formed in the vicinity of the plurality of connection lines to be spaced apart from the plurality of connection lines so that when the display device is stretched, the excessive contraction of some of the plurality of connection lines due to the Poisson's effect may be suppressed.

According to the present disclosure, the excessive contraction of the connection line may be suppressed.

According to the present disclosure, the damage of the connection line due to the excessive contraction may be minimized or reduced.

According to the present disclosure, when the display device is stretched, a reinforcement member which supports the connection line is formed in an area which is contracted by the Poisson effect to protect the connection line so as not to be excessively contracted.

According to the present disclosure, in each area of the display device, a degree of contraction is considered to differentially design a length and the number of reinforcement members to ensure the stretchability of the connection line and protect the connection line so as not to be excessively contracted.

Embodiments of the present disclosure are not limited to the above-mentioned embodiments, and other embodiments, which are not mentioned above, can be clearly understood by those skilled in the art from the following descriptions.

The effects according to the present disclosure are not limited to the contents exemplified above, and more various effects are included in the present specification. Other detailed matters of the embodiments are included in the detailed description and the drawings.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a plan view of a display device according to an embodiment of the present disclosure;

FIGS. 2 and 3 are enlarged plan views of an active area of the display device of FIG. 1;

FIG. 4 is a cross-sectional view of the display device of FIG. 1 along line I-I′ in FIG. 1;

FIG. 5 is a cross-sectional view of the display device of FIG. 2 along line II-II′ in FIG. 2;

FIG. 6 is a schematic plan view of a display device according to an embodiment of the present disclosure in a resting configuration before being stretched and a stretched configuration after being stretched;

FIG. 7 is a schematic plan view of the display device of FIG. 1;

FIGS. 8 and 9 are enlarged plan views of an active area of a display device according to an embodiment of the present disclosure;

FIG. 10 is an enlarged plan view of an active area of a display device according to an embodiment of the present disclosure; and

FIG. 11 is a cross-sectional view of the display device of FIG. 10 along line III-III′.

### DETAILED DESCRIPTION

Advantages and characteristics of the present disclosure and a method of achieving the advantages and characteristics will be clear by referring to embodiments described below in detail together with the accompanying drawings. However, the present disclosure is not limited to the embodiments disclosed herein but will be implemented in various forms. The embodiments are provided by way of example only so that those skilled in the art can fully understand the aspects and techniques of the present disclosure and the scope of the present disclosure.

The shapes, sizes, ratios, angles, numbers, and the like illustrated in the accompanying drawings for describing the embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only.” Any references to singular may include plural unless expressly stated otherwise.

Components are interpreted to include an ordinary error range even if not expressly stated. Except as otherwise noted, the error range may be plus or minus 5% of the stated characteristic. The terms “substantially” and “approximately” are understood to refer to this error range.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, one or more other layers or elements may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

In describing the elements of the present disclosure, terms such as first, second, A, B, (a), (b), etc., may be used. Such terms are used for merely discriminating the corresponding elements from other elements and the corresponding elements are not limited in their essence, sequence, precedence, or number by the terms. It will be understood that when an element is referred to as being “coupled” or “connected to” another element, it can be directly coupled or directly connected to the other element, or intervening other elements may be present therebetween.

The term “at least one” should be understood as including any and all combinations of one or more of the associated listed elements. For example, the meaning of “at least one of a first element, a second element, and a third element” denotes the combination of all elements proposed from two or more of the first element, the second element, and the third element as well as the first element, the second element, or the third element.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, embodiments of the present disclosure will be described in detail with reference to accompanying drawings.

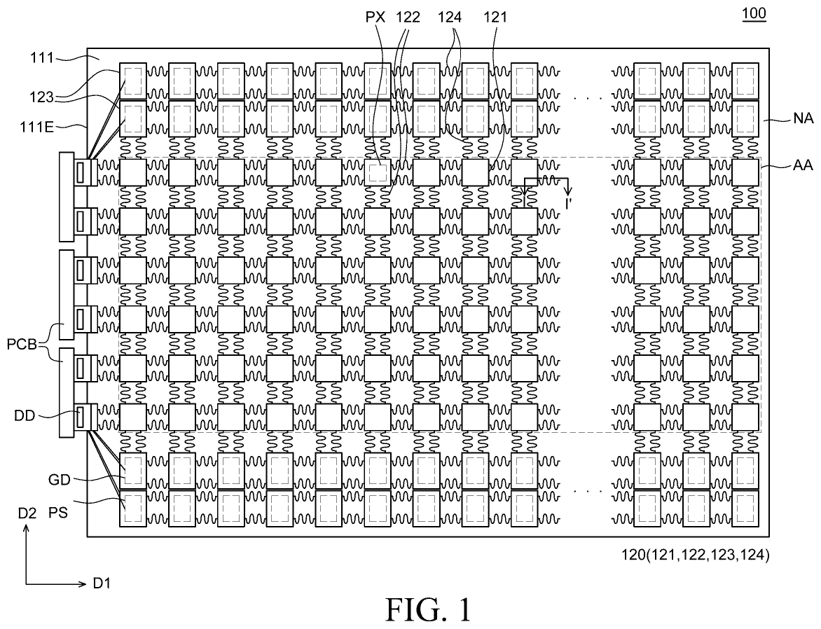

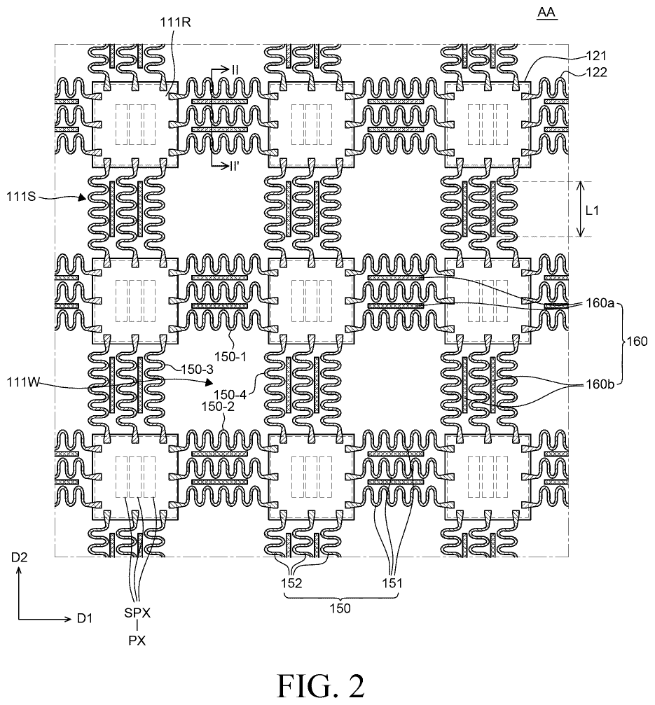

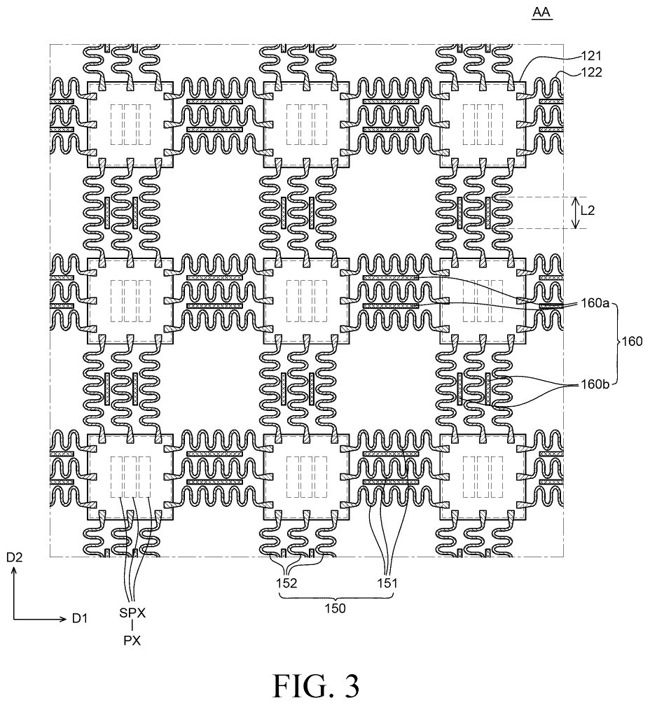

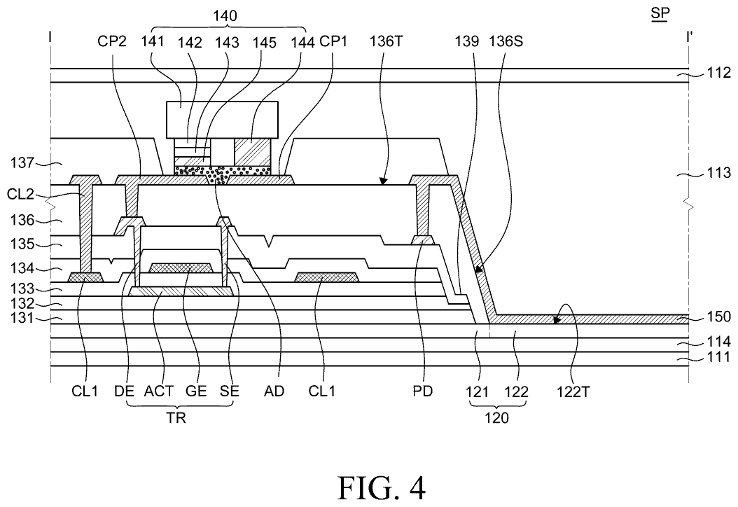

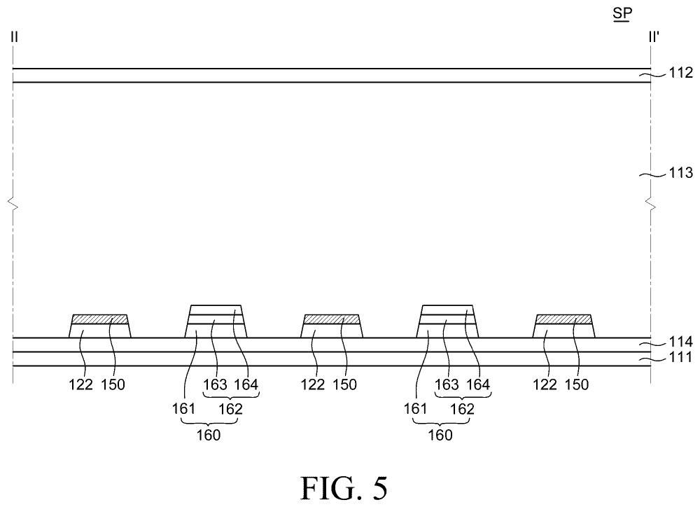

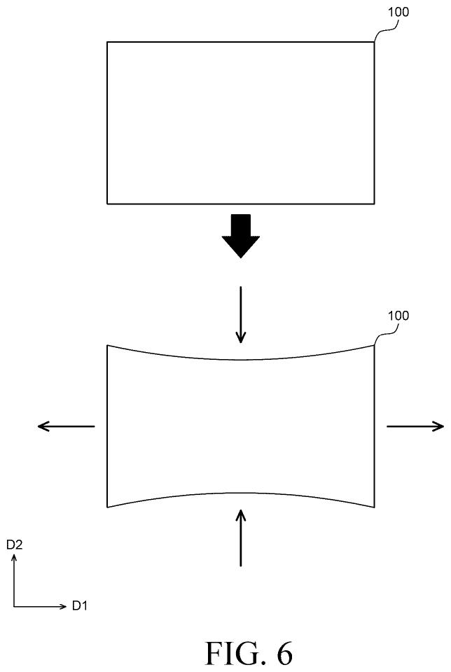

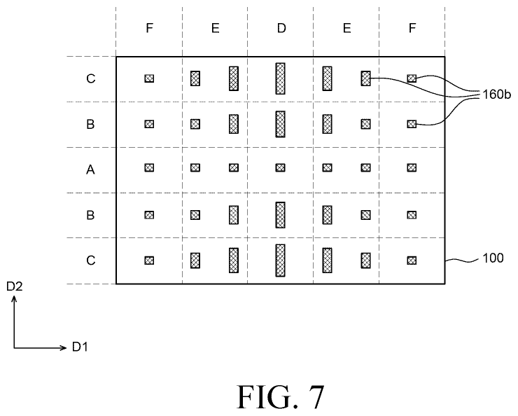

FIG. 1 is a plan view of a display device 100 according to an embodiment of the present disclosure. FIGS. 2 and 3 are enlarged plan views of an active area AA of the display device 100. FIG. 4 is a cross-sectional view of the display device 100 along line I-I′ in FIG. 1. FIG. 5 is a cross-sectional view of the display device 100 along line II-II′ in FIG. 2. FIG. 6 is a schematic plan view of the display device 100 in a relaxed configuration before being stretched and a stretched configuration after being stretched. FIG. 7 is a schematic plan view of the display device 100. Specifically, FIG. 2 is an enlarged plan view of an area of the display device 100 in which a connection line 150 is relatively more contracted and FIG. 3 is an enlarged plan view of an area of the display device 100 in which a connection line 150 is relatively less contracted. FIG. 7 is a schematic plan view of a display device 100 for explaining a length of a second reinforcement member 160b in each area.

First, the display device 100 according to one or more embodiments of the present disclosure is the display device 100 which is capable of displaying images even in a bent or extended state and may also be referred to as a stretchable display device, a flexible display device and an extendable display device. As compared with the general display devices of the related art, the display device 100 has not only a high flexibility, but also stretchability. Therefore, the user may bend or extend the display device 100 and a shape of the display device 100 may be freely changed in accordance with manipulation of a user. For example, when the user pulls the display device 100 by holding ends of the display device, the display device 100 may be extended to the pulling direction of the user. Alternatively, when the user disposes the display device 100 on an external surface which is not flat, the display device 100 may be disposed to be bent in accordance with the shape of the external surface. Further, when a force applied by the user is removed, the display device 100 may return to its original shape. Accordingly, the display device 100 exhibits clastic properties.

Referring to FIGS. 1 to 4 together, the display device 100 includes a lower substrate 111. The lower substrate 111 is a substrate which supports and protects several components of the display device 100. The lower substrate 111 may support a pattern layer 120 on which the pixels PX, the gate driver GD, and the power supply PS are formed.

The display device 100 further includes an upper substrate 112 that is a substrate which covers and protects several components of the display device 100. The upper substrate 112 may cover the pixels PX, the gate driver GD, and the power supply PS.

The lower substrate 111 and the upper substrate 112 are flexible substrates which may be configured by, be formed of, or include an insulating material which is bendable or extendable. For example, the lower substrate 111 and the upper substrate 112 may be formed of a silicon rubber such as polydimethylsiloxane (PDMS) or an elastomer such as polyurethane (PU) or polytetrafluoroethylene (PTFE), among others, and thus, may have a flexibility. Further, the materials of the lower substrate 111 and the upper substrate 112 may be the same, but are not limited thereto and may vary.

The lower substrate 111 and the upper substrate 112 are flexible substrates so as to be reversibly expandable and contractible. Accordingly, the lower substrate 111 may be referred to as a lower stretchable substrate, a lower stretching substrate, a lower extending substrate, a lower ductile substrate, a lower flexible substrate, a first stretchable substrate, a first stretching substrate, a first extending substrate, a first ductile substrate, a first flexible substrate, or the like. The upper substrate 112 may be referred to as an upper stretchable substrate, an upper stretching substrate, an upper extending substrate, an upper ductile substrate, an upper flexible substrate, a second stretchable substrate, a second stretching substrate, a second extending substrate, a second ductile substrate, a second flexible substrate, or the like.

Moduli of elasticity of the lower substrate 111 and the upper substrate 112 may be several MPa to several hundreds of MPa. Further, a ductile breaking rate of the lower substrate 111 and the upper substrate 112 may be 100% or higher. Here, the ductile breaking rate refers to a stretching rate at a timing when an object to be stretched is broken or cracked. A thickness of the lower substrate 111 may be 10 um to 1 mm, but is not limited thereto.

The lower substrate 111 includes an active area AA and a non-active area NA enclosing the active area AA. However, the active area AA and the non-active area NA may not be limited to only the lower substrate 111, but also included for the entire display device 100. Thus, the display device 100 may generally have an active area AA and a non-active area NA at least partially, or fully, surrounding the active area AA, and likewise for the upper substrate 112.

The active area AA is an area in which images are displayed in the display device 100 and a plurality of pixels PX is disposed in the active area AA. Each pixel PX may include a display element and various driving elements for driving the display element. Various driving elements may refer to at least one thin film transistor (TFT) and a capacitor, but are not limited thereto. The plurality of pixels PX may be connected to various wiring lines to be driven, respectively. For example, each of the plurality of pixels PX may be driven by being connected to various wiring lines, such as a scan line, a data line, a high potential voltage line, a low potential voltage line, a reference voltage line, and an initialization voltage line.

The non-active area NA is an area where no image is displayed. The non-active area NA may be an area adjacent to the active area AA. The non-active area NA is adjacent to the active area AA to enclose the active area AA. However, it is not limited thereto so that the non-active area NA corresponds to an area excluding the active area AA from the lower substrate 111 and may be modified and separated in various forms. In the non-active area NA, various components for driving the plurality of pixels PX disposed in the active area AA, such as a gate driver GD and a power supply PS, may be disposed. In the non-active area NA, a plurality of pads connected to the data driver DD and the printed circuit board PCB may be disposed and each pad may be connected to each of the plurality of pixels PX of the active area AA. Some of the above features of the active area AA and non-active area NA are not shown to avoid obscuring the concepts of the disclosure.

The pattern layer 120 is disposed on the lower substrate 111. The pattern layer 120 includes a plurality of plate patterns 121, 123 and a plurality of line patterns 122, 124. Specifically, the pattern layer 120 may include a plurality of first plate patterns 121 and a plurality of first line patterns 122 disposed in the active area AA and a plurality of second plate patterns 123 and a plurality of second line patterns 124 disposed in the non-active area NA.

The plurality of plate patterns 121, 123 is disposed in the active area AA and the non-active area NA. The plurality of plate patterns includes a plurality of first plate patterns 121 and a plurality of second plate patterns 123. The plurality of first plate patterns 121 is disposed in the active area AA of the lower substrate 111 and the plurality of second plate patterns 123 is disposed in the non-active area NA of the lower substrate 111. On the plurality of first plate patterns 121, a plurality of pixels PX may be formed and on the plurality of second plate patterns 123, a gate driver GD and a power supply PS may be formed.

The plurality of first plate patterns 121 and the plurality of second plate patterns 123 may be disposed in the form of separate islands or individual components or areas of material. The plurality of first plate patterns 121 and the plurality of second plate patterns 123 may be individually separated. Therefore, the plurality of first plate patterns 121 and the plurality of second plate patterns 123 may be referred to as first island patterns and second island patterns or first individual patterns and second individual patterns. In an embodiment, the first plate patterns 121 and second plate patterns 123 may be arranged in a matrix of repeating rows and columns with selected spacing between each of the first plate patterns 121 and each of the second plate patterns 123, as well as between outer ones of the first plate patterns 121 and outer ones the second plate patterns 123. This concept is best illustrated in FIG. 1.

A size of each of the plurality of second plate patterns 123 may be larger than a size of each of the plurality of first plate patterns 121. In each of the plurality of second plate patterns 123, one stage of the gate driver GD may be disposed. Therefore, an area occupied by various circuit configurations which configure one stage of the gate driver GD may be relatively larger than an area occupied by one pixel PX so that a size of each of the plurality of second plate patterns 123 may be larger than a size of each of the plurality of first plate patterns 121.

In the meantime, even though it is illustrated in FIG. 1 that the plurality of second plate patterns 123 is disposed in the non-active area NA on both sides of the active area AA in the second direction D2, this is illustrative and non-limiting. The plurality of second plate patterns 123 may be disposed in an arbitrary and selected area of the non-active area NA. Further, even though it is illustrated that the plurality of first plate patterns 121 and the plurality of second plate patterns 123 have a rectangular shape, it is not limited thereto and the shapes of the plurality of first plate patterns 121 and the plurality of second plate patterns 123 may vary in one or more embodiments.

Referring to FIGS. 1 and 2, the plurality of line patterns 122 and 124 is disposed in the active area AA and the non-active area NA. The plurality of line patterns 122 and 124 includes a plurality of first line patterns 122 and a plurality of second line patterns 124.

The plurality of first line patterns 122 is disposed in the active area AA. The plurality of first line patterns 122 is patterns which connect first plate patterns 121 which are adjacent to each other and may be referred to as internal connection patterns. That is, the plurality of first line patterns 122 may be disposed between the plurality of first plate patterns 121 in an internal area of the display 100 to connect internal first plate patterns 121 to each other.

The plurality of second line patterns 124 of the pattern layer 120 is disposed in the non-active area NA. The plurality of second line patterns 124 connects the first plate pattern 121 and the second plate pattern 123 which are adjacent to each other or connects a plurality of adjacent second plate patterns 123 to each other and may be referred to as external connection patterns. The plurality of second line patterns 124 may be disposed between the first plate pattern 121 and the second plate pattern 123 which are adjacent to each other and between the plurality of second plate patterns 123 which is adjacent to each other. For example, the matrix of first plate patterns 121 includes outer first patterns 121 that are adjacent or positioned closest to corresponding ones of the second plate patterns 123. The second line patterns 124 connect these outer first patterns 121 to the second plate patterns 123 as well as the second plate patterns 123 to each other.

The plurality of first line patterns 122 and the plurality of second line patterns 124 have a wavy shape or a wave shape with repeated crests and crests and a selected wavelength, which may be constant or relatively constant along a length of the first and second line patterns 122, 124. For example, the plurality of first line patterns 122 and the plurality of second line patterns 124 may have a sinusoidal shape. However, the shapes of the plurality of first line patterns 122 and the plurality of second line patterns 124 are not limited thereto. For example, the plurality of first line patterns 122 and the plurality of second line patterns 124 may extend in a zigzag pattern. Further, the plurality of first line patterns 122 and the plurality of second line patterns 124 may have various shapes such as a shape in which a plurality of rhombic substrates is connected at their vertexes to be extended or a shape in which semi-circular and quadrant-shaped substrates are connected to each other. Further, the number and the shape of the plurality of first line patterns 122 and the plurality of second line patterns 124 illustrated in FIG. 1 are illustrative and may be changed in various forms depending on the design.

In the meantime, the plurality of first plate patterns 121, the plurality of first line patterns 122, the plurality of second plate patterns 123, and the plurality of second line patterns 124 are rigid patterns. That is, the plurality of first plate patterns 121, the plurality of first line patterns 122, the plurality of second plate patterns 123, and the plurality of second line patterns 124 may be more rigid than the lower substrate 111 and the upper substrate 112.

The plurality of first plate patterns 121, the plurality of first line patterns 122, the plurality of second plate patterns 123, and the plurality of second line patterns 124 which are rigid substrates may be formed of a plastic material having a lower flexibility than the lower substrate 111 and the upper substrate 112. For example, the plurality of first plate patterns 121, the plurality of first line patterns 122, the plurality of second plate patterns 123, and the plurality of second line patterns 124 may be formed of at least one material of polyimide (PI), polyacrylate, and polyacetate, among others. When the plurality of first plate patterns 121, the plurality of first line patterns 122, the plurality of second plate patterns 123, and the plurality of second line patterns 124 are formed of the same material, the plurality of first plate patterns 121, the plurality of first line patterns 122, the plurality of second plate patterns 123, and the plurality of second line patterns 124 may be integrally formed in one layer or the the patterning layer 120. The plurality of first plate patterns 121, the plurality of first line patterns 122, the plurality of second plate patterns 123, and the plurality of second line patterns 124 may also be formed of different materials, in which case, they may be formed by several individual patterns. Variations of the the plurality of first plate patterns 121, the plurality of first line patterns 122, the plurality of second plate patterns 123, and the plurality of second line patterns 124 are not limited to the above non-limiting examples.

Moduli of elasticity of the plurality of first plate patterns 121, the plurality of first line patterns 122, the plurality of second plate patterns 123, and the plurality of second line patterns 124 may be higher than a modulus of elasticity of the lower substrate 111. The modulus of elasticity is a parameter representing a rate of deformation against the stress applied to the substrate and the higher the modulus of elasticity, the higher the hardness. Therefore, the plurality of first plate patterns 121, the plurality of first line patterns 122, the plurality of second plate patterns 123, and the plurality of second line patterns 124 may be referred to as a plurality of first rigid patterns, a plurality of second rigid patterns, a plurality of third rigid patterns, and a plurality of fourth rigid patterns, respectively. Moduli of elasticity of the plurality of first plate patterns 121, the plurality of first line patterns 122, the plurality of second plate patterns 123, and the plurality of second line patterns 124 may be 1000 times higher than the moduli of elasticity of the lower substrate 111 and the upper substrate 112, but the disclosure is not limited thereto.

In the meantime, in some embodiments, the lower substrate 111 may be defined to include a plurality of first lower patterns and a second lower pattern. The plurality of first lower patterns may be an area of the lower substrate 111 overlapping the plurality of first plate patterns 121 and the plurality of second plate patterns 123. The second lower pattern may be a remaining area which does not overlap the plurality of first plate patterns 121 and the plurality of second plate patterns 123.

Further, the upper substrate 112 may be defined to include a plurality of first upper patterns and a second upper pattern. The plurality of first upper patterns of the upper substrate 112 may be an area overlapping the plurality of the first plate patterns 121 and the plurality of second plate patterns 123, but the second upper pattern may be a remaining area which does not overlap the plurality of the first plate patterns 121 and the plurality of second plate patterns 123.

In an embodiment, moduli of elasticity of the plurality of first lower patterns and the first upper pattern may be higher than moduli of elasticity of the second lower pattern and the second upper pattern. For example, the plurality of first lower patterns and the first upper pattern may be formed of the same material as the plurality of first plate patterns 121 and the plurality of second plate patterns 123. The second lower pattern and the second upper pattern may be formed of a material having a modulus of elasticity lower than those of the plurality of first plate patterns 121 and the plurality of second plate patterns 123.

For example, the first lower pattern and the first upper pattern may be formed of polyimide (PI), polyacrylate, polyacetate, or the like. Further, the second lower pattern and the second upper pattern may be formed of silicon rubber such as polydimethylsiloxane (PDMS) or elastomer such as polyurethane (PU) or polytetrafluoroethylene, among others.

The gate driver GD may be mounted on the plurality of second plate patterns 123. The gate driver GD may be formed on the plurality of second plate patterns 123 in a gate in panel (GIP) manner when various components on the plurality of first plate patterns 121 are manufactured. Therefore, various circuit configurations which configure the gate driver GD, such as transistors, capacitors, and wiring lines, may be disposed on the plurality of second plate patterns 123. One stage which is a circuit which configures the gate driver GD and includes transistors, capacitors, and the like may be disposed above each of the plurality of second plate patterns 123. However, the gate driver GD may be mounted in a chip on film (COF) manner, but is not limited thereto.

A power supply PS may be disposed on the plurality of second plate patterns 123. The power supply PS may be formed on the second plate pattern 123 adjacent to the gate driver GD. The power supply PS is a plurality of power blocks patterned when various components on the first plate pattern 121 are manufactured and may be formed on the second plate pattern 123. The power supply PS is electrically connected to the gate driver GD of the non-active area NA and the plurality of pixels PX of the active area AA to supply a driving voltage. Specifically, the power supply PS may be electrically connected to the gate driver GD formed on the second plate pattern 123 and the plurality of pixels PX formed on the first plate pattern 121 by means of the second line pattern 124 and the first line pattern 122. For example, the power supply PS may supply a gate driving voltage and a clock signal to the gate driver GD. The power supply PS may supply the power voltage to each of the plurality of pixels PX.

The printed circuit board PCB is connected to an edge 111E of the lower substrate 111. The printed circuit board PCB is a component which transmits signals and voltages for driving the display element from the control unit to the display element. Therefore, the printed circuit board PCB may also be referred to as a driving substrate. A control unit, such as an IC chip or a circuit unit, may be mounted on the printed circuit board PCB. Further, on the printed circuit board PCB, a memory, a processor, or the like may also be mounted. The printed circuit board PCB provided in the display device 100 may include a stretching area and a non-stretching area to ensure stretchability. In the non-stretching area, an IC chip, a circuit unit, a memory, a processor, and the like may be mounted and in the stretching area, wiring lines which are electrically connected to the IC chip, the circuit unit, the memory, and the processor may be disposed. The stretching area and non-stretching area of the printed circuit board PCB may have different layer stacks and layer compositions to facilitate the different characteristics of these regions or portions of the printed circuit board PCB.

The data driver DD is a component which supplies a data voltage to the plurality of pixels PX disposed in the active area AA. The data driver DD may be configured as an IC chip so that it may also be referred to as a data integrated circuit D-IC. The data driver DD may be mounted in the non-stretching area of the printed circuit board PCB. That is, the data driver DD may be mounted on the printed circuit board PCB in the form of a chip on board (COB). However, even though in FIG. 1, it is illustrated that the data driver DD is mounted in a COB manner, the data driver DD may be mounted in a chip on film (COF), a chip on glass (COG), or a tape carrier package (TCP) manner, among others, and is not limited thereto.

Further, even though in FIG. 1, one data driver DD is disposed so as to correspond to each of a plurality of rows in the direction D1 formed by the plurality of first plate patterns 121 disposed in the active area AA, it is not limited thereto. That is, one data driver DD may be disposed so as to correspond to a plurality of rows formed by the plurality of first plate patterns 121 in the direction D1 in FIG. 1.

Referring to FIGS. 1 and 2, the plurality of first plate patterns 121 is disposed in the active area AA of the lower substrate 111. The plurality of first plate patterns 121 may be disposed to be spaced apart from each other. For example, the plurality of first plate patterns 121 may be disposed in a plurality of rows and a plurality of columns to be disposed in a matrix. For example, the plurality of first plate patterns 121 may be disposed to be spaced apart from each other with a predetermined interval in the first direction D1. The plurality of first plate patterns 121 may be disposed to be spaced apart from each other with a predetermined interval in the second direction D2.

The plurality of first line patterns 122 may be disposed in the active area AA of the lower substrate 111. The plurality of first line patterns 122 is disposed in an area between the plurality of first plate patterns 121 to connect the plurality of first plate patterns 121 to each other. The plurality of first line patterns 122 extends in the first direction D1 or the second direction D2 and may connect the first plate patterns 121 which are adjacent or successive to each other in the first direction D1 or the second direction D2. For example, some first line patterns 122 extending in the first direction D1, among the plurality of first line patterns 122, may connect one pair of first plate patterns 121 which are adjacent or successive to each other in the first direction D1. The remaining first line patterns 122 extending in the second direction D2, among the plurality of first line patterns 122, may connect one pair of first plate patterns 121 which are adjacent or successive to each other in the second direction D2.

A pixel PX including the plurality of sub pixels SPX is disposed in or on the plurality of first plate patterns 121. The sub pixels SPX are individual units or components to emit light. The plurality of sub pixels SPX may form one pixel PX. For example, n sub pixels SPX which form one pixel PX may be disposed in each of the plurality of first plate patterns 121. In the drawings, it is illustrated that one pixel PX includes three sub pixels SPX, but the number of the plurality of sub pixels SPX which forms one pixel PX is not limited thereto. The plurality of sub pixels SPX may include a red sub pixel SPX, a green sub pixel SPX, and a blue sub pixel SPX. The plurality of sub pixels SPX may further include a white sub pixel SPX according to the design of the display device 100, but is not limited thereto.

Each of the plurality of sub pixels SPX includes a light emitting diode 140 (FIG. 4) which is a display element and a pixel circuit for driving the light emitting diode 140.

The light emitting diode 140 may be configured by any one of various elements depending on a type of the display device 100. For example, when the display device 100 is an organic light emitting display device, the light emitting diode 140 may be an organic light emitting diode and when the display device 100 is an inorganic light emitting display device, the light emitting diode 140 may be a light emitting diode LED or a micro LED. Hereinafter, it is assumed that the light emitting diode 140 is a micro LED, but it is not limited thereto.

The pixel circuit supplies the driving current to the light emitting diode 140 to allow the light emitting diode 140 to emit light. The pixel circuit may include a plurality of transistors and capacitors. For example, the pixel circuit may include a plurality of transistors, such as a driving transistor or a switching transistor and a capacitor which is connected to any one of the plurality of transistors. The light emitting diode 140 is shown and described further with reference to FIG. 4.

Referring to FIG. 4, a plurality of inorganic insulating layers is disposed on the plurality of first plate patterns 121. For example, the plurality of inorganic insulating layers may include a multi-buffer layer 131, an active buffer layer 132, a gate insulating layer 133, a first interlayer insulating layer 134, and a second interlayer insulating layer 135. However, in addition to the above-described inorganic insulating layers, another inorganic insulating layer may be additionally disposed or one or more of the above-described inorganic insulating layers may be omitted and a configuration of the plurality of inorganic insulating layers is not limited thereto.

First, the multi-buffer layer 131 is disposed on the plurality of first plate patterns 121 and the active buffer layer 132 is disposed on the multi-buffer layer 131. The multi-buffer layer 131 and the active buffer layer 132 may reduce the permeation of moisture or impurities from the outside of the lower substrate 111 and the first plate pattern 121. The multi-buffer layer 131 and the active buffer layer 132 may protect various components of the display device 100 from the moisture and oxygen of the outside. The multi-buffer layer 131 and the active buffer layer 132 may be formed of an insulating material. For example, the multi-buffer layer 131 and the active buffer layer 132 are each configured by a single layer or a double layer of silicon nitride (SiNx), silicon oxide (SiOx), and silicon oxynitride (SiON), but are not limited thereto. However, the multi-buffer layer 131 and the active buffer layer 132 may be omitted depending on a structure or a characteristic of the display device 100.

In the meantime, the multi-buffer layer 131 and the active buffer layer 132 may be formed above the plurality of first plate patterns 121 and the plurality of second plate patterns 123 and only above the plurality of first plate patterns 121 and the plurality of second plate patterns 123 in some embodiments. The multi-buffer layer 131 and the active buffer layer 132 may overlap the area in which the first plate patterns 121 and the second plate patterns 123 are disposed. The multi-buffer layer 131 and the active buffer layer 132 may not be formed in an area between the plurality of first plate patterns 121 and an area between the plurality of second plate patterns 123. The multi-buffer layer 131 and the active buffer layer 132 which are formed of an inorganic material may be cracked or damaged during a process of stretching the display device 100. Therefore, the multi-buffer layer 131 and the active buffer layer 132 are preferably patterned to have a shape of the plurality of first plate patterns 121 and the plurality of second plate patterns 123 to be formed above the plurality of first plate patterns 121 and the plurality of second plate patterns 123. Accordingly, in the display device 100 according to one or more embodiments of the present disclosure, the multi-buffer layer 131 and the active buffer layer 132 are formed in an area overlapping the plurality of first plate patterns 121 and the plurality of second plate patterns 123 which are rigid patterns, and in some embodiments, only in an area overlapping the plurality of first plate patterns 121 and the plurality of second plate patterns 123. Therefore, even though the display device 100 is bent or stretched to be deformed, the damage of the multi-buffer layer 131 and the active buffer layer 132 may be suppressed so that the damages of various components of the display device 100 may also be suppressed.

The transistor TR is disposed on the buffer layer. The transistor TR includes an active layer ACT, a gate electrode GE, a source electrode SE, and a drain electrode DE.

First, the active layer ACT is disposed on the active buffer layer 132. The active layer ACT may be formed of a semiconductor material, such as an oxide semiconductor, amorphous silicon, polysilicon, and an organic semiconductor, but is not limited thereto.

The gate insulating layer 133 is disposed on the active layer ACT. The gate insulating layer 133 is an insulating layer which insulates the active layer ACT from the gate electrode GE and may be configured by a single layer or a double layer of silicon oxide (SiOx) or silicon nitride (SiNx), but is not limited thereto.

The gate electrode GE is disposed on the gate insulating layer 133. The gate electrode GE may be configured by a conductive material, such as copper (Cu), aluminum (Al), molybdenum (Mo), nickel (Ni), titanium (Ti), chrome (Cr), or an alloy thereof, but is not limited thereto.

The first interlayer insulating layer 134 is disposed on the gate electrode GE and the second interlayer insulating layer 135 is disposed on the first interlayer insulating layer 134. The first interlayer insulating layer 134 and the second interlayer insulating layer 135 are insulating layers which protect components therebelow and may be configured by a single layer or a double layer of silicon oxide (SiOx) or silicon nitride (SiNx), but are not limited thereto.

The source electrode SE and the drain electrode DE are disposed on the second interlayer insulating layer 135. The source electrode SE and the drain electrode DE may be electrically connected to the active layer ACT through a contact hole formed in the second interlayer insulating layer 135, the first interlayer insulating layer 134, and the gate insulating layer 133. The source electrode SE and the drain electrode DE may be configured by a conductive material, such as copper (Cu), aluminum (Al), molybdenum (Mo), nickel (Ni), titanium (Ti), chrome (Cr), or an alloy thereof, but are not limited thereto.

A plurality of first conductive layers CL1 is disposed between the gate insulating layer 133 and the first interlayer insulating layer 134. Each of the plurality of first conductive layers CL1 may configure at least some of the plurality of wiring lines which supply various signals to the sub pixel SPX. For example, the plurality of first conductive layers CL1 may be any one of various wiring lines, such as a scan line, a data line, a reference line, an initialization line, a high potential power line, and a low potential power line. The plurality of first conductive layers CL1 may be configured by a conductive material such as copper (Cu), aluminum (Al), molybdenum (Mo), nickel (Ni), titanium (Ti), chrome (Cr), or an alloy thereof, and may be configured by a single layer or a multi-layered structure thereof, but is not limited thereto.

In the meantime, in FIG. 4, only the plurality of first conductive layers CL1 between the gate insulating layer 133 and the first interlayer insulating layer 134 is illustrated. However, another conductive layer may be further disposed between the first interlayer insulating layer 134 and the second interlayer insulating layer 135 and between the second interlayer insulating layer 135 and the planarization layer 136, but it is not limited thereto.

The plurality of pads PD may be disposed on the second interlayer insulating layer 135. The plurality of pads PD are pads which electrically connect the plurality of connection lines 150 and the plurality of wiring lines on the first plate pattern 121. The plurality of pads PD may be electrically connected to the plurality of connection lines 150 through a contact hole formed in the planarization layer 136. Signals supplied from the plurality of connection lines 150 may be transmitted to various wiring lines on the first plate pattern 121 through the plurality of pads PD. For example, a scan signal, a data voltage, a reference voltage, an initialization voltage, a high potential power voltage, and a low potential power voltage from the plurality of connection lines 150 may be transmitted to the wiring line and the sub pixel SPX on the first plate pattern 121 through the plurality of pads PD. The plurality of pads PD may be formed of the same material as the source electrode SE and the drain electrode DE, for example, any one of molybdenum (Mo), aluminum (Al), chrome (Cr), gold (Au), titanium (Ti), nickel (Ni), neodymium (Nd), and copper (Cu) or an alloy thereof, and configured by a single layer or a multi-layered structure thereof. However, it is not limited thereto.

In the meantime, the gate insulating layer 133, the first interlayer insulating layer 134, and the second interlayer insulating layer 135 are patterned to be similar to the multi-buffer layer 131 and the active buffer layer 132 to be formed in an area overlapping the plurality of first plate patterns 121, and in some embodiments, only in the area overlapping the plurality of first plate patterns 121. The gate insulating layer 133, the first interlayer insulating layer 134, and the second interlayer insulting layer 135 are also formed of the inorganic material, similar to the multi-buffer layer 131 and the active buffer layer 132. Therefore, when the gate insulating layer 133, the first interlayer insulating layer 134 and, the second interlayer insulating layer 135 are stretched while stretching the display device 100, the layers may be damaged. Therefore, the gate insulating layer 133, the first interlayer insulating layer 134, and the second interlayer insulating layer 135 are not formed in an area between the plurality of first plate patterns 121, but are patterned to have a shape of the plurality of first plate patterns 121 to be formed above the plurality of first plate patterns 121. Accordingly, the plurality of inorganic insulating layers which is formed of the inorganic material to be vulnerable to the stretching may be disposed above the plurality of first plate patterns 121, which are rigid substrates.

The planarization layer 136 is disposed on the plurality of pads PD, the transistor TR, and the first interlayer insulating layer 134. The planarization layer 136 may planarize an upper portion of the first plate pattern 121 on which the plurality of pads PD and the transistor TR are disposed. The planarization layer 136 may be configured by a single layer or a plurality of layers and may be formed of an organic material. For example, the planarization layer 136 may be formed of an acrylic organic material, but is not limited thereto. Therefore, the planarization layer 136 may also be referred to as an organic insulating layer.

The planarization layer 136 may be disposed so as to cover top surfaces and side surfaces of the plurality of inorganic insulating layers on the plurality of first plate patterns 121. The planarization layer 136 may be disposed so as to enclose the multi-buffer layer 131, the active buffer layer 132, the gate insulating layer 133, the first interlayer insulating layer 134, and the second interlayer insulating layer 135 which are inorganic insulating layers, together with the plurality of first plate patterns 121. For example, the planarization layer 136 may be disposed so as to cover a side surface of the multi-buffer layer 131, a side surface of the active buffer layer 132, a side surface of the gate insulating layer 133, a side surface of the first interlayer insulating layer 134, a top surface and a side surface of the second interlayer insulating layer 135, and a part of a top surface of the first plate pattern 121.

An inclination angle of the side surface 136S of the planarization layer 136 relative to horizontal may be smaller than an inclination angle relative to horizontal formed by side surfaces of the multi-buffer layer 131, the active buffer layer 132, the gate insulating layer 133, the first interlayer insulating layer 134, and the second interlayer insulating layer 135 that are under the planarization layer 136. For example, the side surface 136S of the planarization layer 136 may have a slope gentler than the slope of each of the side surface of the multi-buffer layer 131, the side surface of the active buffer layer 132, the side surface of the gate insulating layer 133, the side surface of the first interlayer insulating layer 134, and the side surface of the second interlayer insulating layer 135. Therefore, the connection line 150 which extends to the upper portion of the first plate pattern 121 along the side surface 136S of the planarization layer 136 may be disposed with a gentle slope so that when the display device 100 is stretched, the stress generated in the connection line 150 may be reduced. A line 150 with a gentler slope will generally have a longer length than a line with a steeper slope such that the generated stress is distributed over a greater length or distance of the connection line 150, thereby reducing the likelihood of damage to the connection line 150. Therefore, the planarization layer 136 may compensate for the step 139 on the side surface of each of the multi-buffer layer 131, the active buffer layer 132, the gate insulating layer 133, the first interlayer insulating layer 134, and the second interlayer insulating layer 135 to avoid the connection line 150 following the shape of the step 139. If the connection line 150 has a step shape or configuration, the corners may be locations of concentrated stress that increase the likelihood of damage to the connection line 150. Thus, the connection line 150 is preferably formed with as few bends and turns as possible along the side surfaces of the inorganic layers. In an embodiment, the only turn in the direction of the connection line relative to vertical occurs at the interface between the plate and line patterns 121, 122.

Further, the side surface of the planarization layer 136 has a relatively gentle slope so that the crack of the connection line 150 or separation thereof from the side surface of the planarization layer 136 may be suppressed. Accordingly, the planarization layer 136 having a gentle slope may enhance an adhesive strength with the connection line 150 disposed on the side surface of the planarization layer 136.

Next, the plurality of connection lines 150 refers to wiring lines which electrically connect the pads PD on the plurality of first plate patterns 121 and the pads PD on the plurality of second plate patterns 123. The plurality of connection lines 150 is disposed on the plurality of first line patterns 122 and the plurality of second line patterns 124. The plurality of connection lines 150 may extend onto the plurality of first plate patterns 121 to be electrically connected to the plurality of pads PD on the plurality of first plate patterns 121. The plurality of first line patterns 122 is not disposed in an area where the plurality of connection lines 150 is not disposed, among areas between the plurality of first plate patterns 121. Further, even though it is not illustrated in the drawings, the plurality of connection lines 150 is disposed on the plurality of second line patterns 124 to be electrically connected to the pads PD on the plurality of second plate patterns 123 and the pads PD on the plurality of first plate patterns 121.

The plurality of connection lines 150 includes a first connection line 151 and a second connection line 152. The first connection line 151 and the second connection line 152 are disposed between the plurality of first plate patterns 121, between the plurality of second plate patterns 123, and between the plurality of first plate patterns 121 and the plurality of second plate patterns 123. Specifically, the first connection line 151 refers to a wiring line extending in the first direction D1 between successive ones of the plurality of first plate patterns 121, between successive ones of the plurality of second plate patterns 123, and between the plurality of first plate patterns 121 and the plurality of second plate patterns 123, among the connection lines 150. The second connection line 152 refers to a wiring line extending in the second direction D2 between successive ones the plurality of first plate patterns 121, between successive ones of the plurality of second plate patterns 123, and between the plurality of first plate patterns 121 and the plurality of second plate patterns 123. Here, the first direction D1 and the second direction D2 may also be referred to as a row direction and a column direction, respectively.

The plurality of connection lines 150 may be formed of a metal material such as copper (Cu), aluminum (Al), titanium (Ti), and molybdenum (Mo) or a stacked structure of metal materials such as copper/molybdenum-titanium (Cu/Moti) or titanium/aluminum/titanium (Ti/Al/Ti), but is not limited thereto.

In the case of a general display device, various wiring lines such as a plurality of scan lines and a plurality of data lines are disposed to extend between the plurality of sub pixels in a straight line shape and the plurality of sub pixels is connected to one signal line. Therefore, in the general display device, various wiring lines, such as a scan line, a data line, a high potential voltage line, and a reference voltage line, extend from one side to the other side of the display device without being disconnected on the substrate.

In contrast, in the display device 100 according to one or more embodiments of the present disclosure, various wiring lines, such as a scan line, a data line, a high potential voltage line, a reference voltage line, and an initialization voltage line having a straight line shape which are considered to be used for the general display device, are disposed only on the plurality of first plate patterns 121 and the plurality of second plate patterns 123. That is, in the display device 100 according to one or more embodiments of the present disclosure, a straight line-shaped wiring line is disposed only on the plurality of first plate patterns 121 and the plurality of second plate patterns 123.

In the display device 100 according to one or more embodiments of the present disclosure, the pads PD on two adjacent first plate patterns 121 may be connected by the connection lines 150. Accordingly, the connection line 150 electrically connects the pads PD on two adjacent first plate patterns 121. Accordingly, the display device 100 according to one or more embodiments of the present disclosure may include a plurality of connection lines 150 so as to electrically connect various wiring lines, such as a scan line, a data line, a high potential voltage line, and a reference voltage line, between the plurality of first plate patterns 121. For example, the scan line may be disposed on the plurality of first plate patterns 121 disposed to be adjacent to each other or successive to each other in the first direction D1 and the pads PD may be disposed on both ends of the scan line. At this time, the plurality of pads PD on the plurality of first plate patterns 121 adjacent to each other or successive to each other in the first direction D1 may be connected to each other by the first connection line 151 which serves as a scan line. Therefore, the scan line disposed on the plurality of first plate patterns 121 and the first connection line 151 disposed on the first line pattern 122 may serve as one scan line. Further, wiring lines which extend in the first direction D1, among all various wiring lines which may be included in the display device 100, such as an emission signal line, a low potential voltage line, and a high potential voltage line, may also be electrically connected by the first connection line 151, as described above.

Some first connection lines 151, among the plurality of first connection lines 151 of the active area AA, may connect the pads PD on two first plate patterns 121 which are disposed side by side, among the pads PD on the plurality of first plate patterns 121 disposed to be adjacent in the first direction D1. The pads PD on the plurality of first plate patterns 121 disposed in the first direction D1 may be connected by the first connection line 151 serving as a scan line and may transmit one gate voltage. However, the plurality of first connection lines 151 may serve as an emission signal line, a high potential voltage line, or a low potential voltage line, as well as the scan line, but is not limited thereto.

Some second connection lines 152, among the plurality of second connection lines 152, may connect the pads PD to each other on two first plate patterns 121 which are disposed side by side, among the plurality of first plate patterns 121 disposed to be adjacent in the second direction D2. An internal line on the plurality of first plate patterns 121 disposed in the second direction D2 may be connected by the plurality of second connection lines 152 serving as a data line and transmit one data voltage. However, the plurality of second connection lines 152 may serve as data lines, high potential voltage lines, low potential voltage lines, or reference voltage line, but is not limited thereto.

The plurality of connection lines 150 may be disposed to be in contact with a top surface 136T and the side surface 136S of the planarization layer 136 disposed on the first plate pattern 121. The plurality of connection lines 150 may be disposed on the top surface of the first line pattern 122 and both ends thereof extend onto the first plate pattern 121 to be formed.

In some embodiments, there is no need to dispose a rigid pattern in an area in which the first connection line 151 and the second connection line 152 are not disposed, and as such, the plurality of first line patterns 122 may not be disposed in such areas.

A second conductive layer CL2 is disposed on the planarization layer 136. The second conductive layer CL2 may configure at least some of the plurality of wiring lines which supply various signals to the sub pixel SPX. For example, the second conductive layer CL2 may be any one of various wiring lines, such as a scan line, a data line, a reference line, an initialization line, a high potential power line, and a low potential power line. Further, the second conductive layer CL2 may also serve as an electrode which connects the connection line 150 and the plurality of pads PD. The second conductive layer CL2 may be configured by a conductive material, for example, any one of copper (Cu), aluminum (Al), molybdenum (Mo), nickel (Ni), titanium (Ti), and chrome (Cr), or an alloy thereof, and may be configured with a single layer or multi-layered structure, but is not limited thereto.

A connection pad is disposed on the planarization layer 136. The connection pad is a pad for electrically connecting the light emitting diode 140 to the pixel circuit. The connection pad includes a first connection pad CP1 and a second connection pad CP2. The power line and the first electrode 144 of the light emitting diode 140 may be electrically connected by means of the first connection pad CP1. The drain electrode DE of the transistor TR and the second electrode 145 of the light emitting diode 140 may be electrically connected by means of the second connection pad CP2. The first connection pad CP1 may be electrically connected to the connection line 150 which transmits a power voltage. For example, the first connection pad CP1 may integrally be formed with the connection line 150 which transmits a power voltage. The second connection pad CP2 may be electrically connected to the drain electrode DE of the transistor TR through a contact hole formed in the planarization layer 136. Therefore, when the display device 100 is driven, different levels of voltages which are applied to the first connection pad CP1 and the second connection pad CP2 are transmitted to the first electrode 144 and the second electrode 145 of the light emitting diode 140, respectively, so that the light emitting diode 140 may emit light.

A bank 137 is disposed on the plurality of connection pads CP1, CP2, the plurality of connection lines 150, and the planarization layer 136. The bank 137 is disposed in an area between the plurality of sub pixels SPX to reduce the color mixture between the plurality of sub pixels SPX. The bank 137 is disposed so as to cover at least a part of the connection pad CP1, CP2, the connection line 150, and the planarization layer 136. The bank 137 may be formed of an insulating material. The bank 137 includes a black material to block wiring lines which may be visible through the active area AA. For example, the bank 137 may be formed of a carbon-based mixture and specifically, include carbon black. However, it is not limited thereto and the bank 137 may be formed of a transparent insulating material. Even though in the drawings, it is illustrated that a height of the bank 137 is lower than a height of the light emitting diode 140, the present disclosure is not limited thereto and the height of the bank 137 may be equal to the height of the light emitting diode 140.

The light emitting diode 140 is disposed on the connection pad CP1, CP2. The light emitting diode 140 includes a first semiconductor layer 141, an active layer 142, a second semiconductor layer 143, a first electrode 144, and a second electrode 145. The light emitting diode 140 of the display device 100 according to one or more embodiments of the present disclosure has a flip-chip structure in which the first electrode 144 and the second electrode 145 are formed together on one surface, but is not limited thereto.

The second semiconductor layer 143 is disposed on the connection pad CP1, CP2 and the first semiconductor layer 141 is disposed on the second semiconductor layer 143. The first semiconductor layer 141 and the second semiconductor layer 143 may be layers formed by doping n-type and p-type impurities into a specific material. For example, the first semiconductor layer 141 and the second semiconductor layer 143 may be layers doped with n-type and p-type impurities into a material such as gallium nitride (GaN), indium aluminum phosphide (InAlP), or gallium arsenide (GaAs). The p-type impurity may be magnesium (Mg), zinc (Zn), beryllium (Be), and the like, and the n-type impurity may be silicon (Si), germanium, tin (Sn), and the like, but is not limited thereto.

The active layer 142 is disposed between the first semiconductor layer 141 and the second semiconductor layer 143. The active layer 142 may be a light emitting layer of the light emitting diode 140 which emits light. For example, the active layer 142 may be configured as a single layer or a multi-quantum well (MQW) structure. For example, the active layer 142 may be configured by indium gallium nitride (InGaN) or gallium nitride (GaN), but it is not limited thereto.

As described above, the light emitting diode 140 of the display device 100 according to one or more embodiments of the present disclosure may be manufactured by sequentially laminating the first semiconductor layer 141, the active layer 142, and the second semiconductor layer 143, and then etching a predetermined part to form the first electrode 144 and the second electrode 145. In this case, the predetermined part which is a space for separating the first electrode 144 and the second electrode 145 from each other may be etched to expose a part of the first semiconductor layer 141. In other words, surfaces of the light emitting diode 140 on which the first electrode 144 and the second electrode 145 will be disposed are not flat surfaces, but have different height levels.

As described above, the first electrode 144 may be disposed on one surface of the first semiconductor layer 141 exposed in the etched area. Further, the second electrode 145 may be disposed on one surface of the second semiconductor layer 143 disposed in an unetched area.

A connection adhesive layer AD is disposed between the light emitting diode 140 and the connection pad CP1, CP2. The connection adhesive layer AD may be disposed between the first electrode 144 and the second electrode 145 of the light emitting diode 140 and the connection pad CP1, CP2. The connection adhesive layer AD may be a conductive adhesive layer 114 in which conductive balls are dispersed in an insulating base member or substrate. Therefore, when heat or a pressure is applied to the connection adhesive layer AD, the conductive balls are electrically connected in a portion applied with the heat or pressure to have a conductive property and an area which is not pressurized or under the influence of heat may have an insulation property. The first electrode 144 and the second electrode 145 may be electrically connected to the connection pad CP1, CP2 by means of the connection adhesive layer AD. For example, after applying the connection adhesive layer AD on the connection pad CP1, CP2 in an inkjet method, the light emitting diode 140 is transferred to the connection adhesive layer AD and the light emitting diode 140 is pressurized and heated to electrically connect the connection pad CP1, CP2 and the second electrode 145 and the first electrode 144. However, the other part of the connection adhesive layer AD excluding a part of the connection adhesive layer AD disposed between the first electrode 144 and the connection pad CP1, CP2 and a part of the connection adhesive layer AD disposed between the second electrode 145 and the connection pad CP1, CP2 has an insulating property. In other words, the connection adhesive layer AD may be an insulating layer in other regions besides those described above, namely where the connection adhesive layer AD is disposed between the first electrode 144 and the connection pad CP1, CP2 and where the connection adhesive layer AD is disposed between the second electrode 145 and the connection pad CP1, CP2. Even though in the drawings, it is illustrated that the connection adhesive layers AD which cover one pair of connection pads are connected to each other, the connection adhesive layers AD may be separated to be disposed above each of the pair of connection pads.

Next, the upper substrate 112 is disposed on the light emitting diode 140 and the lower substrate 111. The upper substrate 112 is a substrate which supports various components disposed below the upper substrate 112. For example, the upper substrate 112 may be formed by coating and then curing a material which configures the upper substrate 112 above the lower substrate 111 and the first plate pattern 121.

The upper substrate 112 may be formed of the same material as the lower substrate 111. For example, the upper substrate 112 may be formed of a silicon rubber such as polydimethylsiloxane (PDMS) or an elastomer such as polyurethane (PU) or polytetrafluoroethylene (PTFE) and thus have a flexible property. However, the material of the upper substrate 112 is not limited thereto.

Even though not illustrated in FIG. 4, a polarization layer may be disposed on the upper substrate 112. The polarization layer may function to polarize light incident from the outside of the display device 100 to reduce the external light reflection. Further, an optical film, etc., other than the polarization layer may be disposed on the upper substrate 112.

A filling layer 113 is disposed between the lower substrate 111 and the upper substrate 112. The filling layer 113 may be fully filled in an empty space between the lower substrate 111 and the upper substrate 112. For example, the filling layer 113 may be configured by a curable adhesive. Specifically, the material which configures the filling layer 113 is coated on the entire surface of the lower substrate 111 and then is cured so that the filling layer 113 may be disposed between the components disposed on the upper substrate 112 and the lower substrate 111. In an embodiment, the filling layer 113 fills the space between the upper and lower substrate 111, 112, or between the upper substrate 112 and the next successively lower layer, which may be the first semiconductor layer 141, the buffer layer 137, or the connection line 150. Because of the additional layers associated with the first plate patterns 121 relative to the first line patterns 122, a thickness of the filling layer 113 may be less in an area or region corresponding to the first plate patterns 121 than in an area or region corresponding to the first line patterns 122 to provide the overall layer stack or laminate with a uniform thickness across the display. For example, the filling layer 113 may be an optically clear adhesive (OCA) and may be configured by an acrylic adhesive, a silicon-based adhesive, a urethane-based adhesive, and the like.

The adhesive layer 114 may be disposed between the lower substrate 111 and the pattern layer 120. The filling layer 113 may be in contact with a top surface of the adhesive layer 114 exposed from the pattern layer 120. The adhesive layer 114 is a layer for bonding the lower substrate 111 and the pattern layer 120. When the display device 100 is formed, after sequentially forming configurations of the pattern layer 120 and the plurality of sub pixels SPX on a rigid substrate, the rigid substrate and the pattern layer 120 are separated and the lower substrate 111 may be attached below the pattern layer 120. At this time, in order to fix the pattern layer 120 and the lower substrate 111, the adhesive layer 114 may be disposed between the pattern layer 120 and the lower substrate 111. For example, the adhesive layer 114 may be an optically clear adhesive (OCA), but is not limited thereto.

In the meantime, referring now to FIG. 6, when the display device 100 is stretched in the first direction D1, the length of the display device 100 may be increased in the first direction D1, but the length of the display device 100 may be shortened or decreased in the second direction D2. In contrast, when the display device 100 is stretched in the second direction D2, the length of the display device 100 may be increased in the second direction D2, but the length of the display device 100 may be shortened or decreased in the first direction D1. As described above, when the display device 100 is stretched in one direction, the display device 100 may be contracted in the other direction due to the Poisson's effect. According to the Poisson's effect, in order to keep the overall mass of an object constant, if a length of the object is increased in one direction by a specific force, a length may be reduced or decreased in a direction perpendicular to the direction in which the force is applied (i.e., the extension direction). Therefore, a ratio of deformation of an object due to a stress applied to the object is referred to as a Poisson's ratio. Therefore, when a stretchable display device is stretched in the first direction D1, the display device is contracted in the second direction D2 and the connection line disposed in the area in which the display device is contracted may be excessively contracted. Therefore, some connection lines are excessively contracted to generate stress and the connection line may be cracked or shorted in some prior stretchable display solutions.

Accordingly, in the display device 100 according to one or more embodiments of the present disclosure, a plurality of reinforcement members 160 is formed between the plurality of connection lines 150 to protect the some connection lines 150 so as not to be excessively contracted when the display device 100 is stretched. The plurality of reinforcement members 160 may also be referred to as reinforcement structures, segments, lines, portions, regions, elements, components, and the like.

Specifically, referring to FIGS. 2 and 3, the plurality of reinforcement members 160 is disposed in an area between the plurality of connection lines 150. The plurality of reinforcement members 160 includes a plurality of first reinforcement members 160a and a plurality of second reinforcement members 160b. For example, the plurality of first reinforcement members 160a extending in the first direction D1 may be disposed in an area between the first connection lines 151. The plurality of second reinforcement members 160b extending in the second direction D2 may be disposed in an area between the second connection lines 152. The plurality of reinforcement members 160 which is rigid patterns is disposed in the area between the plurality of connection lines 150 to support the plurality of connection lines 150 so as not to be excessively contracted or stretched. The plurality of reinforcement members 160 has a stretchability or flexibility lower than the plurality of connection lines 150 so as to support the connection line 150 in the vicinity of the plurality of reinforcement members 160 so as not to be excessively deformed.

In an embodiment, the lower substrate 111 includes a rigid area or region 111R, a soft area or region 111S, and a plurality of windows 111W. The rigid area 111R corresponds to the reinforcement members 160 and the soft area 111S may be a flexible area that is between and does not include the rigid reinforcement members 160. The plurality of windows 111W are part of the soft area 111S. Specifically, the plurality of windows 111W are bounded by corresponding ones of the connection lines 150, as shown in FIG. 2. The windows 111W are absent of or do not include reinforcement members 160 nor connection lines 150. For example, in FIG. 2, the connection lines 150 include upper, lower, left, and right connection lines 150-1, 150-2, 150-3, and 150-4 that define boundaries of one of the windows 111W. The connection lines 150-1 through 150-4 may be outermost ones of a series of connection lines 150 between four different substrates 120. Or, in other words, the window 111W is an interior space between outermost ones of the connection lines 150-1 through 150-4. The soft area 111S may be a flexible or stretchable area and the plurality of windows 111W may include only flexible material. The reinforcement members 160 and connection lines 150 extend through the soft area 111S between successive ones of the plurality of plate patterns 120. In an embodiment, the plate patterns 120 are substrates that carry light emitting elements.

In an embodiment, the reinforcement members 160 being “rigid” means that the members 160 have a flexibility or elasticity that is less than the connection lines 150. Accordingly, “rigid” is a relative term that means less flexible than the connection lines 150. The first reinforcement members 160a, 160b may have the same or a different length in the first and second directions D1, D2. In addition, the reinforcement members 160 may be located only between successive ones of the connection lines 150 meaning that the reinforcement members 160 are in the spaces between pairs of connection lines 150. In some embodiments, the reinforcement members 160 may also be outside of the connection lines 150 or otherwise associated with only one outer connection line 150.

When the display device 100 is stretched in the second direction D2, the plurality of first reinforcement members 160a may support the plurality of first connection lines 151 extending in the first direction D1 so as not to be excessively contracted. When the display device 100 is stretched in the first direction D1, the plurality of second reinforcement members 160b may support the plurality of second connection lines 152 extending in the second direction D2 so as not to be excessively contracted.

The plurality of reinforcement members 160 may be disposed to be spaced apart from at least one pair of first plate patterns 121 connected to both ends of the plurality of connection lines 150. For example, the plurality of reinforcement members 160 may be disposed to be spaced apart from each of one pair of first plate patterns 121 connected to both ends of the plurality of connection lines 150. If the reinforcement member 160 is connected to both the pair of first plate patterns 121 to be connected to both ends of the connection line 150, an interval between the pair of first plate patterns 121 is inevitably maintained constant by the reinforcement member 160 and it may be difficult to stretch the connection line 150. In other words, it is preferable that the reinforcement members 160 are not coupled to the plate patterns 121 because connecting the reinforcement members 160 to the plate patterns 121 creates a rigid frame that negatively impacts flexibility of the stretchable display 100. Future developments or use of other types of materials or reinforcement members with different characteristics, among other changes, may enable connection of the reinforcement members 160 to the plate patterns 121 while still achieving the advantages described herein. Accordingly, the plurality of reinforcement members 160 is disposed to be spaced apart from at least any one of one pair of first plate patterns 121 which are adjacent to each other to minimize or reduce loss of or reduction in the stretchability of the plurality of connection lines 150.

Further, the plurality of reinforcement members 160 may be disposed to be spaced apart from the plurality of connection lines 150. If the plurality of reinforcement members 160 is directly connected to the plurality of connection lines 150 and the wiring pattern, it is difficult to stretch the plurality of connection lines 150. Accordingly, the plurality of reinforcement members 160 may be disposed to be spaced apart from the plurality of connection lines 150 and the wiring pattern while being disposed in the area between the plurality of connection lines 150.

Referring to FIG. 5, each of the plurality of reinforcement members 160 is configured by a reinforcement pattern layer 161 and an inorganic pattern layer 162. The reinforcement pattern layer 161 is disposed on the lower substrate 111 and the adhesive layer 114 and the inorganic pattern layer 162 is disposed on the reinforcement pattern layer 161.

The reinforcement pattern layer 161 may be formed by the same process with the same material as the pattern layer 120. The reinforcement pattern layer 161 may be formed of a material which is more rigid than the lower substrate 111, like the pattern layer 120, and for example, may be formed of at least one of polyimide (PI), polyacrylate, and polyacetate, among others.

The inorganic pattern layer 162 is disposed on the reinforcement pattern layer 161. The inorganic pattern layer 162 is patterned to have a shape corresponding to the reinforcement pattern layer 161 to be disposed only on the reinforcement pattern layer 161. The inorganic pattern layer 162 may include one or more inorganic films in only one or more than one layer. For example, the inorganic pattern layer 162 may be configured by a first inorganic film 163 on the reinforcement pattern layer 161 and a second inorganic film 164 on the first inorganic film 163. The plurality of inorganic films of the inorganic pattern layer 162 may be formed by the same process with the same material as at least one of the plurality of inorganic insulating layers disposed on the first plate pattern 121.

The first inorganic film 163 and the second inorganic film 164 may be formed by the same process with the same material as the multi-buffer layer 131, the active buffer layer 132, the gate insulating layer 133, the first interlayer insulating layer 134, and the second interlayer insulating layer 135. For example, when the first inorganic film 163 is formed by the same process with the same material as the multi-buffer layer 131, the second inorganic film 164 may be formed by the same process with the same material as any one of the inorganic insulating layers on the multi-buffer layer 131. The inorganic insulating layers on the multi-buffer layer 131 include the active buffer layer 132, the gate insulating layer 133, the first interlayer insulating layer 134, and the second interlayer insulating layer 135. As another example, when the first inorganic film 163 is formed by the same process with the same material as the gate insulating layer 133, the second inorganic film 164 may be formed by the same process with the same material as any one of the first interlayer insulating layer 134 and the second interlayer insulating layer 135 on the gate insulating layer 133. However, the first inorganic film 163 and the second inorganic film 164 may be formed by various combinations, but are not limited thereto.

As the reinforcement pattern layer 161 and the inorganic pattern layer 162 are formed by patterning, the layers 161, 162 may generally have a selected shape. As noted above, it is preferable if the layers 161, 162 are not in contact with the pattern layer 120 nor the connection lines 150, but rather, are spaced from the pattern layer 120 and the connection lines 150. In some embodiments, the reinforcement pattern layer 161 and the inorganic pattern layer 162 may have a rectilinear shape and may have a shape and configuration that differs from the connection lines 150. For example, the reinforcement members 160 may be disposed in a straight line while the connection lines 150 have a wavy shape. Alternatively, the shape of the reinforcement members 160 and the connection lines 150 may be the same. In further embodiments, the reinforcement pattern layer 161 and the inorganic pattern layer 162 may have a trapezoidal shape in cross section that extends in a straight line in the first direction D1 or the second direction D2. Many other configurations are contemplated, and the disclosure includes any other geometric shape as being a possibility for the reinforcement pattern layer 161 and the inorganic pattern layer 162. Further, the reinforcement members 160 generally may have a selected width, thickness, and height.

In the meantime, as described above, when the display device 100 is stretched in the first direction D1 or the second direction D2, the display device 100 may be contracted in the second direction D2 or the first direction D1. The display device 100 may be contracted in a direction perpendicular to a main stretching direction while being stretched toward the main stretching direction. Therefore, the reinforcement member 160 may be configured to have a different length for every area of the display device 100 by considering the main stretching direction of the display device 100 and the Poisson's effect.

Hereinafter, it is assumed that the main stretching direction of the display device 100 is the first direction D1, that is, the display device 100 is stretched mainly in the first direction D1, which results in contraction in the second direction D2.

Referring to FIGS. 6 and 7, when the display device 100 is stretched in the first direction D1, the display device 100 may be contracted in the second direction D2 due to the Poisson's effect. In this case, the second connection line 152 which extends in the second direction D2 may be contracted together with the display device 100 so that the interval between the first plate patterns 121 may be reduced in the second direction D2.

A degree of contraction of the second connection line 152 may vary depending on the area of the display device 100. When the display device 100 is stretched in the first direction D1, the outer peripheral area of the second direction D2 (i.e., the area furthest from the center area of the display device 100) may include second connection lines 152 that are contracted more than second connection lines 152 toward the center area of the display device 100. For example, the plurality of second connection lines 152 disposed in the same column may be contracted to have different lengths and the closer to the edge of the display device 100, the more the plurality of second connection lines 152 may be contracted. For example, referring to FIG. 7, the second connection line 152 is contracted the least in the center area A and the closer to the outer peripheral area C of the second direction D2 from the center area A, the more the second connection line 152 may be contracted. Specifically, area B will have second connection lines 152 contracted further than the lines 152 in area A, and area C will have second connect lines 152 that experience the most contraction of any other area. In each area A, B, C, the connection lines 152 closer to the boundary of the next successive area or at the outer edges of the area will have the greatest contraction among the areas A, B, C. For example, connection lines at the boundary between areas B and C will have greater contraction than connection lines at the bottom of area B near the boundary with area A. Contraction is the greatest at the outer edge of areas C (i.e., at the top and bottom of the schematic display 100 of FIG. 7). Therefore, in the outer peripheral area C, the second connection line 152 may be contracted the most.

When the display device 100 is stretched in the first direction D1, the plurality of second connection lines 152 disposed on the same row may also be contracted with different lengths according to the position. The more adjacent to the center area, the more the plurality of second connection lines 152 disposed on the same row may be contracted. Among the plurality of second connection lines 152 disposed on the same row, a second connection line 152 disposed at the center may be contracted the most and a second connection line 152 disposed at the outermost periphery may be contracted least. That is, the more adjacent to the edge of the display device 100 in the first direction D1, the less the connection line 150 may be contracted. For example, referring to FIG. 7, among the plurality of second connection lines 152 disposed in the center area A, the second connection line 152 located in the center area D is contracted the most and the second connection line 152 located in the outermost peripheral area F may be contracted the least. This is similar to, but opposite of, the contraction for the second direction D2 described above.

Accordingly, when the display device 100 is stretched in the first direction D1, the most contraction may occur in the outer peripheral area of the display device 100 in the second direction D2 and the most contraction may occur in an outer peripheral area located in the center of the outer peripheral area. In other words, the greatest contraction occurs in areas CD, which are central areas in the first direction D1 and outer peripheral areas in the second direction D2. Therefore, each of the plurality of second connection lines 152 disposed in the same row may be contracted with different lengths and each of the plurality of second connection lines 152 disposed in the same column may be also contracted with different lengths.

Therefore, the second reinforcement member 160b may be formed to have different lengths in consideration of the degree of contraction of the second connection line 152 for every area of the display device 100. For example, in an area where the second connection line 152 is contracted the most, the length of the second reinforcement member 160b may be formed to be longer and in an area where the second connection line 152 is contracted less, the length of the second reinforcement member 160b may be formed to be shorter. The lengths of the plurality of second reinforcement members 160b disposed in the same row or the same column may be gradually changed.

Specifically, the more adjacent to the outer peripheral area of the second direction D2 from the center area, the longer the length of the second reinforcement member 160b may be formed. For example, referring to FIG. 7, in the center area A, the second connection line 152 is contracted the least so that the length of the second reinforcement member 160b may be formed to be short. The more adjacent to the area B and the outer peripheral area C from the center area A, the more the second connection line 152 is contracted so that the length of the second reinforcement member 160b may be formed to be longer.

The more adjacent to the outer peripheral area of the first direction D1 from the center area, the shorter the length of the second reinforcement member 160b may be formed. For example, among the plurality of second reinforcement members 160b disposed on the same row, a second reinforcement member 160b located in the center area D in which the second connection line 152 is contracted the most may be formed to have the largest length. Among the plurality of second reinforcement members 160b disposed on the same row, a second reinforcement member 160b located in the outer peripheral area F in which the second connection line 152 is contracted the least may be formed to have the smallest length. Therefore, the closer to the area E and the center area D from the outer peripheral area F, the longer the length of the second reinforcement member 160b may be formed.

For example, referring to FIGS. 2 and 3 together, the plurality of second reinforcement members 160b may be formed to have different lengths for every area. In the area in which the second connection line 152 is contracted relatively more, as illustrated in FIG. 2, the length of the second reinforcement member 160b disposed between the second connection lines 152 may be formed to be long. In the area in which the second connection line 152 is contracted relatively less, as illustrated in FIG. 3, the length of the second reinforcement member 160b disposed between the second connection lines 152 may be formed to be short. For example, as illustrated in FIG. 2, the second reinforcement member 160b in an area in which the second connection line 152 is contracted relatively more may be formed to have a first length L1. Further, as illustrated in FIG. 3, the second reinforcement member 160b in an area in which the second connection line 152 is contracted relatively less may be formed to have a second length L2 which is shorter than the first length L1.

At this time, the second reinforcement member 160b may be formed to have a different length for every area or the length may gradually vary. For example, among the plurality of second reinforcement members 160b disposed on the same row, all the plurality of second reinforcement members 160b located in the area D may be formed to have the same length or formed to have different lengths, respectively, depending on the position of the second reinforcement members 160b.

Accordingly, in the area in which the connection line 150 is contracted relatively more, the reinforcement member 160 is formed to have a larger length to more firmly support the connection line 150 and suppress the crack, etc., caused by the excessive contraction of the connection line 150. In some embodiments, the width and/or height of the reinforcement members 160 may also be varied to change the characteristics of the reinforcement member 160. For example, a wider reinforcement member 160 that otherwise has the same characteristics as another reinforcement member 160 is expected to be more rigid. As a result, other dimensions of the reinforcement member 160 may also be varied to vary the rigidity or support provided across the display 100. In some embodiments, the available width between the connection lines 150 limits the maximum width of the reinforcement members 160 and the space between the substrates 111, 112 limits the maximum height of the reinforcement members 160, but other configurations of the display 100 may allow for more flexibility for varying the width and height. In one or more embodiments, a material composition of the reinforcement members 160 may also be varied to change the flexibility or rigidity of the reinforcement members 160.

Therefore, the main stretching direction of the display device 100 is the first direction D1, but the display device 100 may also be stretched in the second direction D2. Therefore, in preparation for the case that the display device 100 is stretched in the second direction D2, in the display device 100, the plurality of first reinforcement members 160a extending in the first direction D1 which is perpendicular to the second direction D2 may be disposed between the plurality of first connection lines 151. Even though in the drawing, it is illustrated that the plurality of first reinforcement members 160a has the same length, the plurality of first reinforcement members 160a may be formed to have different lengths for every area or may be formed to have the same length in the entire display device 100. However, it is not limited thereto.

In the meantime, when the main stretching direction of the display device 100 is the second direction D2, the display device 100 may be contracted in the first direction D1 and the plurality of first connection lines 151 may be contracted. A degree of contraction of the plurality of first connection lines 151 also may vary for every area of the display device 100. For example, in the center area of the display device 100, the first connection lines 151 that are closer to the outer peripheral area of the first direction D1 may be contracted further than the first connection lines 151 toward the center of the center area of the display device 100. The more adjacent to the edge of the display device 100, the more the plurality of first connection lines 151 disposed on the same row may be contracted. The more adjacent to the edge of the display device 100 in the second direction D2, the less the plurality of first connection lines 151 disposed on the same column may be contracted. The more adjacent to the center of the display device 100, the more the plurality of first connection lines 151 disposed on the same column may be contracted.

The plurality of first reinforcement members 160a may also be designed with different lengths in consideration of a degree of contraction of the plurality of first connection lines 151. For example, in an area where the plurality of first connection lines 151 is contracted more, the length of the first reinforcement member 160a may be formed to be longer and in an area where the plurality of first connection lines 151 is contracted relatively less, the length of the first reinforcement member 160a may be formed to be short. As noted above, other characteristics of the first reinforcement members 160a may also be varied to change the characteristics and rigidity of the reinforcement members 160a.

Accordingly, in the display device 100 according to one or more embodiments of the present disclosure, the plurality of reinforcement members 160 may be disposed between the connection lines 150 to reduce the excessive contraction of some connection lines 150 due to the Poisson's effect when the display device 100 is stretched. The plurality of reinforcement members 160 is disposed in the area between the plurality of connection lines 150 to support the plurality of connection lines 150 so as not to be excessively contracted. Specifically, the length of the display device 100 is reduced in a direction perpendicular to the stretching direction due to the Poisson's effect so that some connection lines 150 extending in the direction perpendicular to the stretching direction, among the plurality of connection lines 150, may be contracted. At this time, excessive contraction of some connection lines 150 may be suppressed by the reinforcement member 160. Accordingly, when the display device 100 is stretched, the plurality of reinforcement members 160 may protect some connection lines 150 extending in the direction perpendicular to the stretching direction from being excessively contracted to be damaged and improve the reliability of the plurality of connection lines 150.

In the display device 100 according to one or more embodiments of the present disclosure, the plurality of reinforcement members 160 may be designed to have different lengths in consideration of the Poisson's effect and a degree of contraction of the plurality of connection lines 150 thereby. Specifically, the plurality of connection lines 150 may be contracted relatively more in the outer peripheral area of the display device 100 than in the center area of the display device 100. Therefore, a longer reinforcement member 160 is formed in an outer peripheral area in which the plurality of connection lines 150 may be easily excessively contracted or damaged to suppress the damage of the plurality of connection lines 150. Further, the more adjacent to the center region of the display 100 in the outer peripheral area, the more the plurality of connection lines 150 may be contracted. Therefore, the more adjacent to the center, the longer the length of the plurality of reinforcement members 160 disposed in the outer peripheral area. Therefore, the lengths of the plurality of reinforcement members 160 are set to be different in consideration of a contraction deviation of the plurality of connection lines 150 in each area. This is best illustrated in FIG. 7.

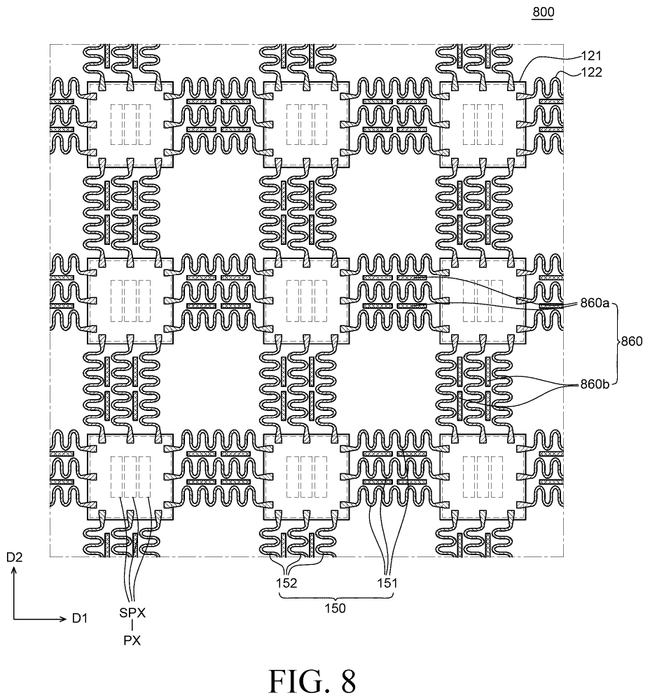

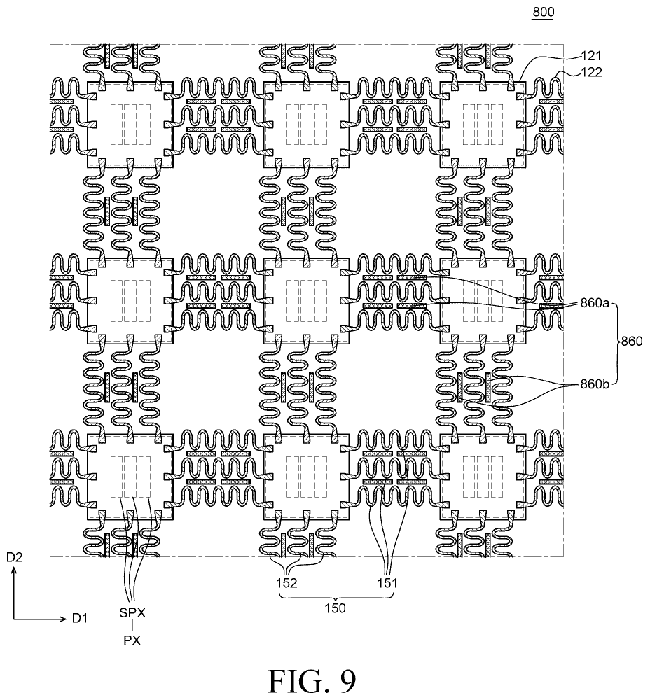

FIGS. 8 and 9 are enlarged plan views of an active area of a display device according to one or more embodiments of the present disclosure. Specifically, FIG. 8 is an enlarged plan view of an area in which a connection line 150 is relatively more contracted and FIG. 9 is an enlarged plan view of an area in which a connection line 150 is relatively less contracted. The only difference between a display device 800 of FIGS. 8 and 9 and the display device 100 of FIGS. 1 to 7 is placement of a plurality of reinforcement members 860, but the other configurations are substantially the same, so that a redundant description will be omitted.

Referring to FIGS. 8 and 9, one or more reinforcement members 860 are disposed in each area between the plurality of connection lines 150. One or more first reinforcement members 860a are disposed in an area between one pair of first connection lines 151 which are adjacent or successive to each other and one or more second reinforcement members 860b are disposed in an area between one pair of second connection lines 152 which are adjacent or successive to each other. The number of the plurality of reinforcement members 860 may vary in consideration of the degree of contraction of the connection line 150 and a main stretching direction of the display device 800. In an embodiment, the entirety of the display 800 may include the reinforcement members 860, or less than the entirety of the display 800 may include the reinforcement members 860. For example, the display 800 may include reinforcement members 860 only in outer peripheral areas of excessive contraction in some embodiments. Each reinforcement member 860 may also be a single, integral, unitary component or body, or may include multiple separate and constituent parts.

For example, when the main stretching direction of the display device 800 is the first direction D1, the display device 800 may be contracted in the second direction D2 and the plurality of second connection lines 152 may also be contracted together. At this time, the degree of contraction may vary depending on the position of the plurality of second connection lines 152 and the number of the plurality of second reinforcement members 160b to be disposed may be set to be different depending on the degree of contraction of the plurality of second connection lines 152. The plurality of reinforcement members 860 disposed between one pair of connection lines 150 may be disposed to be spaced apart from each other.

For example, FIG. 8 illustrates an area in which the plurality of second connection lines 152 is contracted relatively more and a larger number of second reinforcement members 160b may be disposed in each area between the plurality of second connection lines 152. For example, in the area in which the plurality of second connection lines 152 is excessively contracted, two second reinforcement members 160b are disposed in the area between one pair of second connection lines 152 which are adjacent to each other to suppress excessive contraction of the second connection line 152.

For example, FIG. 9 illustrates an area in which the plurality of second connection lines 152 is contracted relatively less and a smaller number of second reinforcement members 160b may be disposed in each area between the plurality of second connection lines 152. For example, in the area in which the plurality of second connection lines 152 is not contracted much, one second reinforcement member 160b is disposed in the area between one pair of second connection lines 152 which are adjacent to each other to suppress excessive contraction of the second connection line 152.

Therefore, in the area where the plurality of second connection lines 152 is contracted relatively more, the number of second reinforcement members 160b may be increased and in the area where the plurality of second connection lines 152 is contracted relatively less, the number of the second reinforcement member 160b may be reduced. The number of the plurality of second reinforcement members 160b to be disposed may vary depending on the degree of contraction of the plurality of second connection lines 152.

In the meantime, the main stretching direction of the display device 800 is the first direction D1, but the display device 800 may also be stretched in the second direction D2. Therefore, in preparation for the case that the display device 800 is stretched in the second direction D2, in the display device 800, the plurality of first reinforcement members 160a may be disposed between the plurality of first connection lines 151. Even though in the drawings, it is illustrated that two first reinforcement members 160a are disposed between one pair of first connection lines 151 which are adjacent to each other, the number of the plurality of first reinforcement members 160a to be disposed may vary for every area, like the second reinforcement member 160b. However, it is not limited thereto.

Accordingly, in the display device 800 according to one or more embodiments of the present disclosure, the plurality of reinforcement members 860 which is spaced apart from each other is disposed between one pair of connection lines 150 to further improve the stretchability of the plurality of connection lines 150 and suppress the excessive contraction of the connection lines 150. The plurality of reinforcement members 860 is disposed between one pair of connection lines 150 which are adjacent to each other and may be disposed to be spaced apart from each other. Therefore, each of the plurality of reinforcement members 860 which is disposed to be spaced apart from each other partially supports only some of the plurality of connection lines 150 so that the plurality of connection lines 150 may be more easily stretched. Further, the plurality of reinforcement members 860 partially supports the plurality of connection lines 150 to suppress the plurality of connection lines 150 from being excessively contracted. Further, the number of the plurality of reinforcement members 860 to be disposed may vary depending on the degree of contraction of the plurality of connection lines 150. For example, in an area in which the excessive contraction of the connection line 150 is not severe, a smaller number of reinforcement members 860 is disposed so that the reinforcement members 860 may suppress the excessive contraction of the connection line 150 without interfering with the stretching of the connection line 150. Accordingly, the number of reinforcement members 860 to be disposed may vary in consideration of the stretchability and the degree of contraction of the connection line 150.

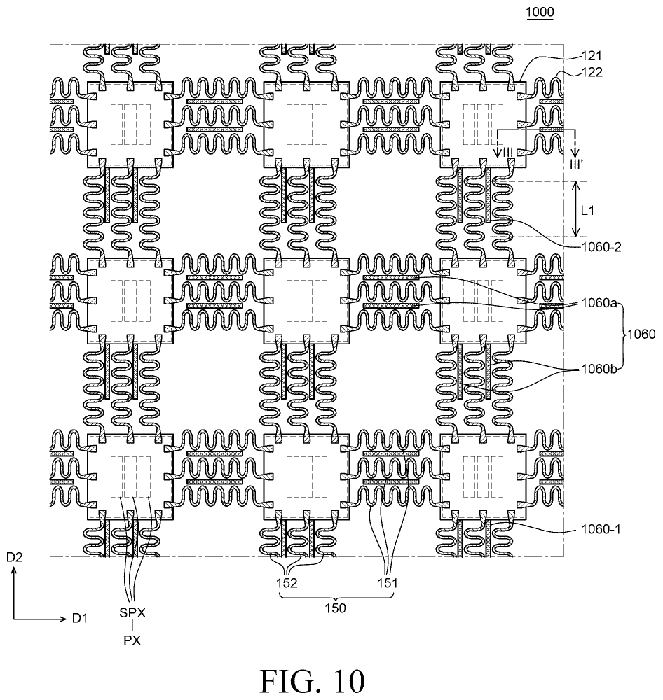

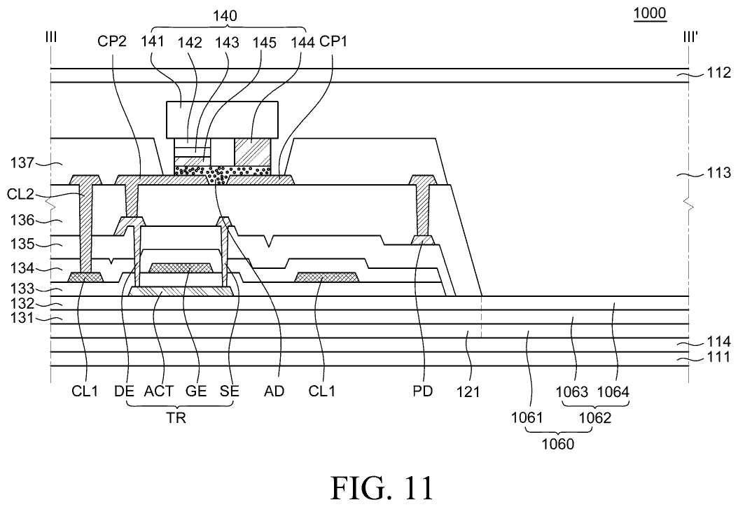

FIG. 10 is an enlarged plan view of an active area of a display device 1000 according to one or more embodiments of the present disclosure. FIG. 11 is a cross-sectional view of the display device 1000 along line III-III′ in FIG. 10. The only difference between the display device 1000 of FIGS. 10 and 11 and the display device 100 of FIGS. 1 to 7 is a plurality of reinforcement members 1060, but the other configurations are substantially the same, so that a redundant description will be omitted.

Referring to FIG. 10, one end portions 1060-1 of at least some of a plurality of reinforcement members 1060 may be connected to the first plate pattern 121. For example, one end portion 1060E of a second reinforcement member 1060b, among the plurality of reinforcement members 1060, may be connected to the first plate pattern 121. The other end portion 1060-2 of the second reinforcement member 1060b may be spaced apart from the first plate pattern 121. One pair of first plate patterns 121 which are opposite to each other with the second reinforcement member 1060b therebetween is disposed and the second reinforcement member 1060b is connected to one first plate pattern of one pair of first plate patterns 121 and is spaced apart from the other first plate pattern 121. In an embodiment, a position of the reinforcement members 1060 may be selected relative to the first plate pattern 121. For example, one of the first and second ends 1060-1, 1060-2 may be coupled or joined to a corresponding first plate pattern 121 while the other end is not attached to a plate pattern 121 and is spaced from the plate patterns 121. The position of the reinforcement members 1060 can also be selected to be anywhere in between successive ones of the plate patterns 121 or the spaces between the plate patterns 121.

Referring to FIG. 11, the reinforcement member 1060 which is connected to the first plate pattern 121 may be connected to the first plate pattern 121 and the inorganic insulating layer on the first plate pattern 121. Specifically, the reinforcement member 1060 includes a reinforcement pattern layer 1061 and an inorganic pattern layer 1062 including a first inorganic film 1063 and a second inorganic film 1064. One end portion of the reinforcement pattern layer 1061 is connected to the first plate pattern 121 and may be integrally formed with the first plate pattern 121 or may be a separate component coupled to the first plate pattern 121.

The first inorganic film 1063 and the second inorganic film 1064 may be connected to any one of a plurality of inorganic insulating layers on the first plate pattern 121. For example, the first inorganic film 1063 may be connected to or integrally formed with the multi-buffer layer 131 and the second inorganic film 1064 may be connected to or integrally formed with the active buffer layer 132. However, the first inorganic film 1063 and the second inorganic film 1064 may also be connected to or integrally formed with any one of the gate insulating layer 133, the first interlayer insulating layer 134, and the second interlayer insulating layer 135 other than the multi-buffer layer 131 and the active buffer layer 132.

In the meantime, even though it is illustrated that the reinforcement member 1060 is connected to only one first plate pattern 121 between one pair of adjacent first plate patterns 121, the reinforcement member 1060 may also be connected to each of one pair of first plate patterns 121. In this case, two reinforcement members 1060 which are opposite to each other are disposed to be spaced apart from each other to allow the connection line 150 to be stretched. Each reinforcement member 1060 may have the same position relative to the plate patterns 121 as the other reinforcement members 160, or each reinforcement member 160 may have a selected position relative to the plate patterns 121 that is the same or different to at least some or all of the other reinforcement members 160.

In the display device 1000 according to one or more embodiments of the present disclosure, one end portion 1060-1, which may be an outermost end 1060-1, of each of the plurality of reinforcement members 1060 is connected to the first plate pattern 121 to suppress excessive contraction of the plurality of connection lines 150. The plurality of reinforcement members 1060 may be formed by the same process as the first plate pattern 121 and the inorganic insulating layers on the first plate pattern 121. Even though the plurality of reinforcement members 1060 is connected to the first plate pattern 121, the other end portions 1060-2, which may be an outermost end, of the plurality of reinforcement members 1060 are spaced apart from the other first plate patterns 121 so that the connection line 150 between one pair of first plate patterns 121 may be easily stretched.

In view of the above, embodiments of the present disclosure can also be described or summarized as follows.

According to an aspect of the present disclosure, a display device includes a stretchable lower substrate, a plurality of plate patterns which is disposed on the lower substrate to be spaced apart from each other, a plurality of connection lines disposed between the plurality of plate patterns, and a plurality of reinforcement members disposed between the plurality of connection lines. The plurality of reinforcement members is spaced apart from the plurality of connection lines.

One end portions of the plurality of reinforcement members may be connected to the plurality of plate patterns, respectively, and the other end portions may be spaced apart from the plurality of plate patterns.

Each of the plurality of reinforcement members may include a reinforcement pattern layer disposed on the lower substrate, and an inorganic pattern layer which is disposed on the reinforcement pattern layer and includes one or more inorganic films.

The display device may further include a plurality of inorganic insulating layers disposed above the plurality of plate patterns, respectively. The inorganic pattern layer may be formed of the same material as at least any one of the plurality of inorganic insulating layers.

One end portion of the reinforcement pattern layer may be connected to the plate pattern and the inorganic pattern layer may be connected to the at least any one of the plurality of inorganic insulating layers.

The plurality of connection lines may include a plurality of first connection lines extending in a first direction, and a plurality of second connection lines extending in a second direction perpendicular to the first direction, and the plurality of reinforcement members may include a plurality of first reinforcement members extending in the first direction, and a plurality of second reinforcement members extending in the second direction.

When the lower substrate is stretched in a first direction, the lower substrate may be contracted in a second direction perpendicular to the first direction.

The plurality of reinforcement members may be formed to have different lengths, respectively.

The more adjacent to an outer peripheral area of the second direction from a center area of the lower substrate, the longer the plurality of reinforcement members may be configured.

The more adjacent to the center area, the longer some reinforcement members disposed on the same line along the first direction, among the plurality of reinforcement members, may be configured.

The number of the plurality of reinforcement members disposed in a center area of the lower substrate may be smaller than the number of the plurality of reinforcement members disposed in an outer peripheral area of the second direction.

The one reinforcement member may be disposed between the plurality of connection lines disposed in the center area and the plurality of reinforcement members may be disposed between the plurality of connection lines disposed in the outer peripheral area of the second direction.

The plurality of reinforcement members which is disposed in the outer peripheral area of the second direction may be disposed to be spaced apart from each other.

In an embodiment, a display device may be summarized as including: a stretchable substrate; a plurality of connection lines disposed on the stretchable substrate; and a plurality of reinforcement members disposed between the plurality of connection lines, wherein the plurality of reinforcement members includes first reinforcement members in a first area of the stretchable substrate and second reinforcement members in a second area of the stretchable substrate, and wherein a length of the first reinforcement members is different from a length of the second reinforcement members.

In an embodiment, the display device further includes a plurality of plate patterns disposed on the stretchable substrate, the plurality of connection lines disposed between the plurality of plate patterns.

In an embodiment, the first area is a central area in a first direction and a second direction of the stretchable substrate, and the second area is an outer peripheral area in the first direction or the second direction of the stretchable substrate.

In an embodiment, the length of the second reinforcement members increases from the first area toward the second area.

In an embodiment, the plurality of reinforcement members are spaced apart from the plurality of connection lines.

In an embodiment, a display device may be summarized as including: a stretchable substrate; a plurality of connection lines disposed on the stretchable substrate; and a plurality of reinforcement members disposed between the plurality of connection lines, wherein the plurality of reinforcement members increase in length or number from a center region of the stretchable substrate toward an outer peripheral region of the stretchable substrate.

In an embodiment, the display device may further include a plurality of plate patterns disposed on the stretchable substrate, the plurality of connection lines disposed between the plurality of plate patterns.

In an embodiment, the outer peripheral region is a central outer peripheral region of the stretchable substrate.

In an embodiment, the plurality of reinforcement members are spaced apart from the plurality of connection lines.

Although the embodiments of the present disclosure have been described in detail with reference to the accompanying drawings, the present disclosure is not limited thereto and may be embodied in many different forms without departing from the technical concept of the present disclosure. Therefore, the embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. All the technical concepts and the equivalent scope of the present disclosure should be construed as falling within the scope of the present disclosure.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a stretchable lower substrate including a rigid area and a soft area, the soft area including a plurality of windows;
a plurality of plate patterns disposed on the stretchable lower substrate and spaced apart from each other, the plurality of plate patterns being the rigid area of the stretchable lower substrate;
a plurality of connection lines disposed in the soft area between the plurality of plate patterns; and
a plurality of reinforcement members disposed between the plurality of connection lines in the soft area,
wherein the plurality of reinforcement members are spaced apart from the plurality of connection lines, and
wherein the plurality of windows are defined by outermost ones of the connection lines between the plurality of plate patterns.

2. The display device of claim 1, wherein the plurality of connection lines and the plurality of reinforcement members are absent from the plurality of windows.

3. The display device of claim 1, wherein the plurality of windows include only flexible material.

4. The display device according to claim 1, wherein first ends of at least some of the plurality of reinforcement members are connected to corresponding ones of the plurality of plate patterns, respectively, and second ends of the at least some of the plurality of reinforcement members are spaced apart from the plurality of plate patterns.

5. The display device according to claim 1, wherein each of the plurality of reinforcement members includes:
a reinforcement pattern layer disposed on the stretchable lower substrate; and
an inorganic pattern layer disposed on the reinforcement pattern layer, the inorganic pattern layer including one or more inorganic films.

6. The display device according to claim 5, further comprising:
a plurality of inorganic insulating layers disposed on the plurality of plate patterns, respectively,
wherein the inorganic pattern layer is a same material as at least any one of the plurality of inorganic insulating layers.

7. The display device according to claim 6, wherein a first end of the reinforcement pattern layer is coupled to a corresponding one of the plurality of plate patterns and the inorganic pattern layer is coupled to the at least any one of the plurality of inorganic insulating layers.

8. The display device according to claim 1, wherein the plurality of connection lines includes:
a plurality of first connection lines extending in a first direction; and
a plurality of second connection lines extending in a second direction perpendicular to the first direction, and
wherein the plurality of reinforcement members includes:
a plurality of first reinforcement members extending in the first direction; and
a plurality of second reinforcement members extending in the second direction.

9. The display device according to claim 1, wherein first ones of the plurality of reinforcement members have different lengths than second ones of the plurality of reinforcement members.

10. The display device according to claim 9, wherein a length of the plurality of reinforcement members increases from a center area of the stretchable lower substrate toward an outer peripheral area of the stretchable lower substrate in the second direction.

11. The display device according to claim 10, wherein the first ones of the plurality of reinforcement members are disposed on a same line along the first direction, and a length of the first ones of the plurality of reinforcement members increases toward the center area of the stretchable lower substrate.

12. The display device according to claim 8, wherein a number of the plurality of reinforcement members disposed in a center area of the stretchable lower substrate is less than a number of the plurality of reinforcement members disposed in an outer peripheral area of the lower substrate in the second direction.

13. The display device according to claim 12, wherein one of the plurality of reinforcement member is disposed between the plurality of connection lines disposed in the center area and at least two of the plurality of reinforcement members are disposed between the plurality of connection lines disposed in the outer peripheral area of the second direction.

14. The display device according to claim 13, wherein the plurality of reinforcement members disposed in the outer peripheral area of the second direction are spaced apart from each other.

15. A display device, comprising:
a stretchable substrate;
a plurality of connection lines disposed on the stretchable substrate; and
a plurality of reinforcement members disposed between the plurality of connection lines,
wherein the plurality of reinforcement members includes first reinforcement members in a first area of the stretchable substrate and second reinforcement members in a second area of the stretchable substrate, and
wherein a length of the first reinforcement members is different from a length of the second reinforcement members.

16. The display device of claim 15, further comprising:
a plurality of plate patterns disposed on the stretchable substrate, the plurality of connection lines disposed between the plurality of plate patterns.

17. The display device of claim 15, wherein the first area is a central area in a first direction and a second direction of the stretchable substrate, and the second area is an outer peripheral area in the first direction or the second direction of the stretchable substrate.

18. The display device of claim 17, wherein the length of the second reinforcement members increases from the first area toward the second area.

19. The display device of claim 15, wherein the plurality of reinforcement members are spaced apart from the plurality of connection lines.

20. A display device, comprising:
a stretchable substrate;
a plurality of connection lines disposed on the stretchable substrate; and
a plurality of reinforcement members disposed between the plurality of connection lines,
wherein the plurality of reinforcement members increase in length or number from a center region of the stretchable substrate toward an outer peripheral region of the stretchable substrate.

21. The display device of claim 20, further comprising:
a plurality of plate patterns disposed on the stretchable substrate, the plurality of connection lines disposed between the plurality of plate patterns.

22. The display device of claim 20, wherein the outer peripheral region is a central outer peripheral region of the stretchable substrate.

23. The display device of claim 20, wherein the plurality of reinforcement members are spaced apart from the plurality of connection lines.
